(19) United States
(12) Patent Application Publication
(10) Pub. No.: US 2015/0287901 A1
(43) Pub. Date: Oct. 8, 2015

(54) FLEXIBLE LEAD FRAME FOR MULTI-LEG PACKAGE ASSEMBLY

(71) Applicant: Alphabet Energy, Inc., Hayward, CA (US)

(72) Inventors: Adam Lorimer, Walnut Creek, CA (US); Jordan Chase, Oakland, CA (US); Sasi Bhushan Beera, Fremont, CA (US); Mario Aguirre, Livermore, CA (US); Hitesh Arora, Fremont, CA (US); Douglas Crane, Richmond, CA (US)

(21) Appl. No.: 14/679,837

(22) Filed: Apr. 6, 2015

Related U.S. Application Data
(60) Provisional application No. 61/976,301, filed on Apr. 7, 2014.

(51) Int. Cl. H01L 35/32; H01L 35/34

(52) U.S. Cl. CPC H01L 35/32; H01L 35/34

(57) ABSTRACT

Thermoelectric structures include a flexible substrate; a plurality of conductive shunts; and a plurality of thermoelectric legs that are in thermal and electrical communication with the thermoelectric legs via thermal and electrical paths. In some embodiments, the paths are through apertures in the flexible substrate, and the flexible substrate can be substantially out of the thermal and electrical paths. Some embodiments include a circuit board coupled to the flexible substrate, and a bend in the flexible substrate can be disposed between the plurality of conductive shunts and the circuit board. In some embodiments, a plurality of perforations are defined through the flexible substrate and can be configured to rupture responsive to a temperature condition that otherwise would damage one or more of the thermal and electrical paths, said rupture inhibiting such damage. Other embodiments, and methods, are provided.

### CROSS REFERENCE TO RELATED APPLICATIONS

This application claims the benefit of U.S. Provisional Patent Application No. 61/976,301, filed Apr. 7, 2014 and entitled “Flexible Lead Frame for Multi-Leg Package Assembly,” the entire contents of which are incorporated by reference herein for all purposes.

This patent application also is related to U.S. patent application Ser. No. 14/053,452, filed on Oct. 14, 2013, commonly assigned and incorporated by reference herein for all purposes.

### FIELD

The present invention is directed to semiconductor manufacture technology. More particularly, the invention provides a flexible lead frame structure for forming a multi-leg package (MLP) assembly. Merely by way of an example, it has been applied for packaging a plurality of thermoelectric N-type/P-type legs on a MLP substrate for the manufacture of a thermoelectric module. It would be recognized that the invention has a much broader range of applicability.

### BACKGROUND

Thermoelectric (TE) devices are often packaged using a plurality of thermoelectric legs arranged in multiple serial chain configurations on a base structure. Each of the plurality of thermoelectric legs is made by, or includes, either p-type or n-type thermoelectric material. The thermoelectric (TE) material, either p-type or n-type, is selected to be, or to include, a semiconductor characterized by high electrical conductivity and relatively high thermal resistivity. One or more p-type TE legs are pairwise-coupled to one or more n-type TE legs via a conductor from each direction in a serial chain or electrically in series-thermally in parallel or electrically in parallel-thermally in parallel configuration, one conductor being coupled at one end region of the TE leg and another conductor being coupled at another end region of the TE leg. When a bias voltage is applied across the top/bottom regions of the thermoelectric device using the two conductors as two electrodes, a temperature difference is generated so that the thermoelectric device can be used as a refrigeration (e.g., Peltier) device. When the thermoelectric device is subjected to a thermal junction with conductors at first end regions of the TE legs being attached to a cold side of the junction and conductors at second end regions of the TE legs being in contact with a hot side of the junction, the thermoelectric device is able to generate electrical voltage across the junction as an energy conversion (e.g., Seebeck) device.

The energy conversion efficiency of thermoelectric devices can be measured by a so-called thermal power density or “thermoelectric figure of merit” ZT, where ZT is equal to TS² σ/k where T is the temperature, S the Seebeck coefficient, σ the electrical conductivity, and k the thermal conductivity of the thermoelectric material. In order to drive up the value of ZT of thermoelectric devices utilizing the Seebeck effect, searching for high performance thermoelectric materials and developing low cost manufacturing processes are major concerns. For example, employing well established planar silicon processing technologies for fabricating silicon-based TE materials has shed light on new development of high power density and low cost thermoelectric devices capable of being used for energy conversion in an environment that could not be done before by any conventional thermoelectric device, such as waste-heat recovery in an ultra-high temperature gradient. However, new material combinations and new environmental requirements reveal the needs of improved techniques for packaging thermoelectric devices.

For example, mounting a plurality of TE legs in a serial chain configuration between two base plates has been employed to make multi-leg package (MLP) thermo-electric modules/packages capable of operating in environments having high temperature gradients which cause high thermal stress in the package. Therefore, choosing the materials of the MLP so as to have matching coefficients of thermal expansion (CTE), and designing the package for the thermal gradients between the hot and cold side becomes useful, and potentially even paramount. TE packages typically have three core components: TE legs, metallic interconnects, and dielectric substrates. Traditionally, ceramic materials are used as the dielectric substrates (also referred to as lead frames or base plates) owing to their high dielectric strength, robustness, and high thermal conductivity. However, ceramics are relatively, or very, rigid and when operating in high thermal gradients can contribute to extreme thermally-induced stresses in the package.

### SUMMARY

Accordingly, it is highly desirable to look for flexible materials as alternatives to ceramics for at least one of the two base plates in the multi-leg package (MLP). This flexibility can facilitate the manufacturing process as well as allow the package to adapt to various application environments. Polyimide (also referred to by the trade name KAPTON® and commercially available from E. I. du Pont de Nemours and Company, Wilmington, Del.) flexible circuits were originally designed as a replacement for bulky wire harnesses. They have high dielectric strength and flexibility but have very poor thermal conductivity (k=0.12 W/m K). It is believed that using polyimide to replace the ceramic base plate that is attached, e.g., directly attached, to thermoelectric (TE) legs, considerable additional thermal resistance would be added to the package, greatly decreasing its effectiveness.

Therefore, it is desired to improve the MLP thermoelectric packaging technique so that at least one base plate can be flexible for facilitating installation in various environments and at the same time being amenable to high temperature gradients. Embodiments of using polyimide as a flexible material with a designated structure for providing a flexible lead frame to the MLP of a thermoelectric module while preventing additional thermal resistance in each of a plurality of heat flow pathways are presented throughout this specification. Depending upon the embodiment, one or more benefits may be achieved. These benefits and various additional objects, features, and advantages of the present invention can be fully appreciated with reference to the detailed description and accompanying drawings that follow.

Under one aspect, a thermoelectric structure includes a flexible substrate including a plurality of apertures defined therethrough; a plurality of conductive shunts disposed over the flexible substrate; and a plurality of thermoelectric legs. The conductive shunts can be in thermal and electrical communication with the thermoelectric legs via thermal and electrical paths passing through the apertures. The flexible substrate can be substantially out of the thermal and electrical paths.

In some embodiments, the thermoelectric structure further is configured to be coupled to a first heat source or sink and to a second heat source or sink. The thermoelectric structure further can include a base plate coupled to at least a subset of the plurality of conductive legs and to the first heat source or sink. The plurality of conductive shunts can be coupled to the second heat source or sink, the plurality of conductive shunts being disposed between the flexible substrate and the second heat source or sink such that the flexible substrate substantially does not impede thermal transport between the second heat source or sink and the plurality of conductive shunts.

In some embodiments, the flexible substrate includes polyimide.

In some embodiments, the plurality of thermoelectric legs includes an N-type thermoelectric leg and a P-type thermoelectric leg, a conductive shunt being in thermal and electrical communication with the N-type thermoelectric leg and with the P-type thermoelectric leg. For example, the conductive shunt can be in thermal and electrical communication with the N-type thermoelectric leg via a first aperture, and the conductive shunt can be in thermal and electrical communication with the P-type thermoelectric leg via a second aperture that is different than the first aperture.

In some embodiments, the plurality of thermoelectric legs includes an N-type thermoelectric leg and two or more P-type thermoelectric legs, a conductive shunt being in thermal and electrical communication with the N-type thermoelectric leg and with the two or more P-type thermoelectric legs. For example, the conductive shunt can be in thermal and electrical communication with the N-type thermoelectric leg via a first aperture, and the conductive shunt can be in thermal and electrical communication with each of the two or more P-type thermoelectric legs via corresponding apertures that are different than the first aperture.

In some embodiments the plurality of thermoelectric legs can include two or more N-type thermoelectric legs and a P-type thermoelectric leg, and the method can include placing a conductive shunt in thermal and electrical communication with the two or more N-type thermoelectric legs and with the P-type thermoelectric leg. Illustratively, the method can include placing the conductive shunt in thermal and electrical communication with the two or more N-type thermoelectric legs via one or more corresponding first apertures, and placing the conductive shunt in thermal and electrical communication with the P-type thermoelectric leg via a corresponding aperture that is different than the first apertures.

Some embodiments further include a circuit board coupled to the flexible substrate, a bend in the flexible substrate being disposed between the plurality of conductive shunts and the circuit board.

In some embodiments, the flexible substrate further includes a plurality of perforations defined therethrough, the perforations being configured to rupture responsive to a temperature condition that otherwise would damage one or more of the thermal and electrical paths, said rupture inhibiting such damage.

Some embodiments further include a base plate to which the plurality of thermoelectric legs are coupled, a notch being defined in the base plate so as to partially relieve thermal stress and allow a small degree of bending flexibility.

In some embodiments, the plurality of thermoelectric legs includes a plurality of N-type thermoelectric legs having a first area and a plurality of P-type thermoelectric legs having a second area, a pattern of the apertures being selected so as to maximize a packing fraction of the thermoelectric legs and so as to optimize a ratio of the first area to the second area. In some embodiments, each N-type thermoelectric leg has a first aspect ratio and each P-type thermoelectric leg has a second aspect ratio, the pattern of the apertures further being selected so as to optimize a ratio of the first aspect ratio to the second aspect ratio.

Under another aspect, a method of making a thermoelectric structure includes providing a flexible substrate including a plurality of apertures defined therethrough; providing a plurality of conductive shunts disposed over the flexible substrate; and providing a plurality of thermoelectric legs. The conductive shunts can be in thermal and electrical communication with the thermoelectric legs via thermal and electrical paths passing through the apertures. The flexible substrate can be substantially out of the thermal and electrical paths.

In some embodiments, the thermoelectric structure further is configured to be coupled to a first heat source or sink and to a second heat source or sink. The thermoelectric structure further can include a base plate, and the method can include coupling such base plate to at least a subset of the plurality of conductive legs and to the first heat source or sink. The method can include coupling the plurality of conductive shunts to the second heat source or sink such that the plurality of conductive shunts are disposed between the flexible substrate and the second heat source or sink such that the flexible substrate substantially does not impede thermal transport between the second heat source or sink and the plurality of conductive shunts.

In some embodiments, the flexible substrate includes polyimide.

In some embodiments, the method further includes defining the apertures through the flexible substrate using cutting. For example, the cutting can include laser cutting.

In some embodiments, the plurality of thermoelectric legs includes an N-type thermoelectric leg and a P-type thermoelectric leg, and the method includes placing a conductive shunt in thermal and electrical communication with the N-type thermoelectric leg and with the P-type thermoelectric leg. For example, the method can include placing the conductive shunt in thermal and electrical communication with the N-type thermoelectric leg via a first aperture, and placing the conductive shunt in thermal and electrical communication with the P-type thermoelectric leg via a second aperture that is different than the first aperture.

In some embodiments, the plurality of thermoelectric legs includes an N-type thermoelectric leg and two or more P-type thermoelectric legs, and the method includes placing a conductive shunt in thermal and electrical communication with the N-type thermoelectric leg and with the two or more P-type thermoelectric legs. For example, the method can include placing the conductive shunt in thermal and electrical communication with the N-type thermoelectric leg via a first aperture, and placing the conductive shunt in thermal and electrical communication with each of the two or more P-type thermoelectric legs via corresponding apertures that are different than the first aperture.

In some embodiments, the plurality of thermoelectric legs includes two or more N-type thermoelectric legs and a P-type thermoelectric leg, and the method includes placing a conductive shunt in thermal and electrical communication with the two or more N-type thermoelectric legs and with the P-type thermoelectric leg. For example, the method can include placing the conductive shunt in thermal and electrical communication with each of the two or more N-type thermoelectric legs via one or more first apertures, and placing the conductive shunt in thermal and electrical communication with the P-type thermoelectric leg via a corresponding aperture that is different than the first apertures.

In some embodiments, the method further includes coupling a circuit board to the flexible substrate and defining a bend in the flexible substrate, the bend being disposed between the plurality of conductive shunts and the circuit board.

In some embodiments, the method further includes defining through the flexible substrate a plurality of perforations, the perforations being configured to rupture responsive to a temperature condition that otherwise would damage one or more of the thermal and electrical paths, said rupture inhibiting such damage.

In some embodiments, the method further includes coupling the plurality of thermoelectric legs to a base plate and defining a notch in the base plate so as to partially relieve thermal stress and allow a small degree of bending flexibility.

In some embodiments, the plurality of thermoelectric legs includes a plurality of N-type thermoelectric legs having a first area and a plurality of P-type thermoelectric legs having a second area. The method can include selecting a pattern of the apertures so as to maximize a packing fraction of the thermoelectric legs and so as to optimize a ratio of the first area to the second area. In some embodiments, each N-type thermoelectric leg has a first aspect ratio and each P-type thermoelectric leg has a second aspect ratio, the method further including selecting the pattern of the apertures so as to optimize a ratio of the first aspect ratio to the second aspect ratio.

Under another aspect, a thermoelectric structure includes a flexible substrate; a plurality of conductive shunts disposed over the flexible substrate; a plurality of thermoelectric legs; and a circuit board coupled to the flexible substrate. The conductive shunts can be in thermal and electrical communication with the thermoelectric legs. A bend in the flexible substrate can be disposed between the plurality of conductive shunts and the circuit board.

Under another aspect, a method of making a thermoelectric structure includes providing a flexible substrate; providing a plurality of conductive shunts disposed over the flexible substrate; providing a plurality of thermoelectric legs; providing a circuit board; bending the flexible substrate so as to define a bend in the flexible substrate; and coupling the circuit board to the flexible substrate. The conductive shunts can be in thermal and electrical communication with the thermoelectric legs. The bend in the flexible substrate can be disposed between the plurality of conductive shunts and the circuit board.

Under yet another aspect, a thermoelectric structure includes a plurality of conductive shunts; and a plurality of thermoelectric legs. The plurality of conductive shunts are in direct thermal and electrical communication with the thermoelectric legs via a conductor.

Under still another aspect, an intermediate thermoelectric structure includes a flexible substrate; a plurality of conductive shunts removably disposed over the flexible substrate; and a plurality of thermoelectric legs. The plurality of conductive shunts can be in thermal and electrical communication with the thermoelectric legs.

Under another aspect, a method of making a thermoelectric structure includes providing a flexible substrate; providing a plurality of conductive shunts disposed over the flexible substrate; providing a plurality of thermoelectric legs; disposing the plurality of conductive shunts in thermal and electrical communication with the thermoelectric legs; and after disposing the plurality of conductive shunts in thermal and electrical communication with the thermoelectric legs, removing the flexible substrate.

Under still another aspect, a thermoelectric structure includes a flexible substrate including a plurality of perforations defined therein; a plurality of conductive shunts disposed over the flexible substrate; and a plurality of thermoelectric legs. The plurality of conductive shunts can be in thermal and electrical communication with the thermoelectric legs via thermal and electrical paths. The perforations can be configured to rupture responsive to a temperature condition that otherwise would damage one or more of the thermal and electrical paths, said rupture inhibiting such damage.

Under another aspect, a method of protecting a thermoelectric structure is provided. The thermoelectric structure includes a flexible substrate, a plurality of conductive shunts disposed over the flexible substrate, and a plurality of thermoelectric legs in thermal and electrical communication with the conductive shunts via thermal and electrical paths. The method can include defining perforations through the flexible substrate; and rupturing the flexible substrate along one or more of the perforations responsive to a thermal condition that otherwise would damage one or more of the thermal and electrical paths, said rupture inhibiting such damage.

### BRIEF DESCRIPTION OF DRAWINGS

FIG. 1 is a simplified diagram showing a partial sectional view of a multi-leg package (MLP) with a series of paired TE legs mounted on a flexible base structure for forming a thermoelectric module, according to one exemplary embodiment of the present invention.

FIG. 2 is a simplified diagram showing a top view of an exemplary flexible lead frame for a MLP for forming a thermoelectric module, according to one exemplary embodiment of the present invention.

FIG. 3 is a simplified diagram showing a bottom view of the exemplary flexible lead frame shown in FIG. 2 for a MLP for forming a thermoelectric module, according to one exemplary embodiment of the present invention.

FIGS. 4A-4D are simplified diagrams showing alternative exemplary flexible lead frames for a MLP for forming a thermoelectric module, according to one exemplary embodiment of the present invention.

FIG. 5A illustrates an exemplary method for forming a MLP for forming a thermoelectric module including a flexible lead frame, according to one exemplary embodiment of the present invention.

FIG. 5B illustrates another exemplary method for forming a MLP for forming a thermoelectric module including a flexible lead frame, according to one exemplary embodiment of the present invention.

FIG. 5C illustrates another exemplary method for forming a MLP for forming a thermoelectric module including a flexible lead frame, according to one exemplary embodiment of the present invention.

FIG. 6 is a simplified diagram showing an alternative exemplary flexible lead frame for a MLP for forming a thermoelectric module, according to one exemplary embodiment of the present invention.

FIGS. 7A-7B are simplified diagrams showing alternative exemplary flexible lead frames for a MLP for forming a thermoelectric module, according to one exemplary embodiment of the present invention.

FIGS. 8A-8C illustrate exemplary structures formed during a method for coupling a flexible lead frame to a circuit board, according to one exemplary embodiment of the present invention.

FIGS. 9A-9B are simplified diagrams showing alternative exemplary flexible lead frames for a MLP for forming a thermoelectric module, according to one exemplary embodiment of the present invention.

FIG. 9C illustrates an exemplary method of protecting a thermoelectric structure from an otherwise damaging thermal condition, according to one exemplary embodiment of the present invention.

### DETAILED DESCRIPTION

The present invention is directed to semiconductor manufacture technology. More particularly, the invention provides a flexible lead frame structure for forming a multi-leg package (MLP) assembly. Merely by way of an example, it has been applied for packaging a plurality of thermoelectric N-type/P-type legs on a MLP substrate for the manufacture of a thermoelectric module. It would be recognized that the invention has a much broader range of applicability.

In some embodiments, a flexible lead frame is provided. For example, the flexible nature of a polyimide film or other flexible substrate is incorporated with a conductive connector sheet to form a lead frame. The flexible polyimide film is used as a carrier substrate onto which a plurality of conductive shunts are disposed, e.g., laminated. In some embodiments, by pre-cutting the polyimide film, desired holes can be formed for exposing the conductive shunts directly to bond with thermoelectric (TE) legs when using a multi-leg packaging process to form a thermoelectric module with enhanced thermal flux through the TE legs. Utilizing the poor thermal conductivity of the polyimide film, the heat loss due to radiation and convection through open space between the TE legs from the hot-side heat source to cold-side heat sink is reduced.

As used herein, “flexible” is intended to mean non-rigid, or bendable under normal use. For example, a “flexible” material can be flexed responsive to forces that can be exerted based on mechanical or thermal stresses during installation or use of a thermoelectric device so as to reduce or inhibit damage to or or failure of one or more materials of the thermoelectric device that otherwise may result from such mechanical or thermal stresses. Flexible materials that can be suitable for use in the present thermoelectric devices include polymers such as polyimide.

In some embodiments, a thermoelectric structure is provided. The structure can include a flexible substrate including a plurality of apertures defined therethrough, a plurality of conductive shunts disposed over the flexible substrate, and a plurality of TE legs. The conductive shunts can be in thermal and electrical communication with the thermoelectric legs via thermal and electrical paths passing through the apertures, and the flexible substrate can be substantially out of the thermal and electrical paths. In some embodiments, the thermoelectric structure further is configured to be coupled to a first heat source or sink and to a second heat source or sink. The thermoelectric structure further can include a base plate coupled to at least a subset of the plurality of conductive legs and to the first heat source or sink. The plurality of conductive shunts can be coupled to the second heat source or sink, the plurality of conductive shunts being disposed between the flexible substrate and the second heat source or sink such that the flexible substrate substantially does not impede thermal transport between the second heat source or sink and the plurality of conductive shunts.

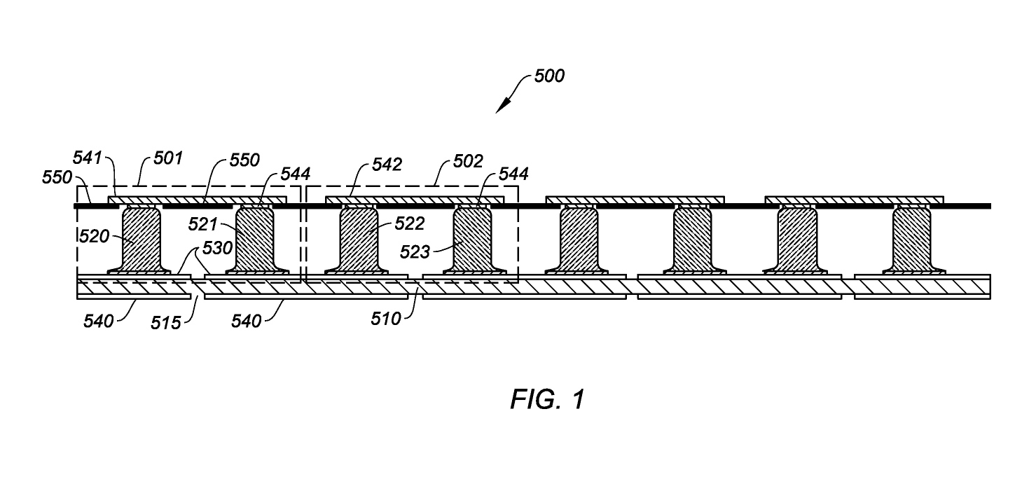

For example, FIG. 1 is a simplified diagram showing a partial sectional view of a MLP with a series of paired TE legs mounted on a base structure for forming a thermoelectric module, according to one embodiment of the present invention. This diagram is merely an example, which should not unduly limit the scope of the claims. One of ordinary skill in the art would recognize many variations, alternatives, and modifications. The MLP can be coupled to a first heat source or sink and to a second heat source or sink (not specifically illustrated). Such heat sources or sinks optionally can be, but need not necessarily, be considered to be part of the MLP.

As shown in FIG. 1, the MLP 500 includes a series of TE legs 520, 521, 522, 523, . . . selectively paired to form a series of n-p thermoelectric unicouples (e.g., thermoelectric unicouples 501 and 502) and is placed with alignment onto a base plate 510. In an example, the thermoelectric unicouple 501 includes a conductive shunt 541 bonded to top ends of two TE legs 520 and 521, one being a n-type TE leg and another being a p-type TE leg. The neighboring thermoelectric unicouple 502 includes another conductive shunt 542 bonded to top ends of two other TE legs 522 and 523. In yet another example, each of the conductive shunts 541 and 542 is thermally and electrically conductive.

In one embodiment, the base plate 510 is electrically insulating but highly thermally conductive. For example, the base plate 510 is made of, or includes, one or more ceramic materials. In another example, the ceramic materials are selected to be, or to include, silicon nitride (Si₃N₄). Other exemplary ceramic materials could include alumina (Al₂O₃) or aluminum nitride (AlN). In another embodiment, one surface side of the base plate 510 is attached to a plurality of metal contact pads 530 and positioned according to predetermined locations on the thermoelectric module respectively for bonding a plurality of TE legs. For example, each of the plurality of metal contact pads 530 is thermally and electrically conductive, which forms electrical/thermal contacts with two TE legs 521 and 522 respectively belonging to two neighboring unicouples 501 and 502. In another embodiment, the other surface side of the base plate 510 is also attached to a plurality of metal contact pads 540. For example, each of the plurality of metal contact pads 540 is thermally and electrically conductive, and can be configured and arranged for bonding with a first heat source or sink, e.g., a hot-side heat exchanger (not shown). In another example, the plurality of metal contact pads 540 is aligned, or substantially aligned, with the plurality of metal contact pads 530, so that a direct, or direct, thermal pathway can be formed from the pad 540 to the aligned pad 530 to allow heat flowing from the first heat source or sink, e.g., hot-side heat exchanger, through the thermally-conductive base plate 510 to reach each of the plurality of TE legs. Each of the plurality of conductive pads, 530 or 540, is electrically separated from each other (e.g., by base plate 510) so that no, or substantially no, electrical current can be shorted from one pad to a neighboring pad. Between two neighboring pads 540, a notch 515 can be added to the base plate 510 to provide certain degrees of freedom for partially relieving thermal stress on the hot-side contacts and allowing a small degree of bending flexibility for mounting the MLP packaged TE module 500 on a non-flat surface of the heat source. The notch 515 may also be used for guiding a cut of the base plate 510 into separate smaller pieces after the formation of the whole thermoelectric module (wherein all other parts have been held together).

In some embodiments, in order to assemble a large thermoelectric module using an MLP, e.g., MLP 500 such as shown in FIG. 1, a plurality of TE legs (520, 521, 522, 523, . . . ) can be included in each serial-chain configuration, and a plurality of such serial-chain configurations are aligned to form a two-dimensional array of TE legs over a large area of the base plate 510 according to certain embodiments. For example, in one nonlimiting embodiment, the base plate 510 is a rectangular-shaped plate attached to N×M metal contact pads 530 and N×M metal contact pads 540, wherein N and M are integers greater than 1. In another example, each metal contact pad 530 is aligned to bond with four TE legs (two other TE legs are not visible in this sectional view of FIG. 1). Other configurations suitably can be used.

Additionally, in some embodiments, in order to assemble the thermoelectric module from the MLP 500, as shown in FIG. 1, the plurality of TE legs in a serial-chain or other suitable configuration is associated with a plurality of conductive shunts 541 respectively placed on top ends of a pair of TE legs out of the plurality of TE legs to form a thermoelectric unicouple 501 including one n-type TE leg and one p-type TE leg. Optionally, the TE legs can be coupled to the conductive shunts via conductor 544, e.g., solder, sintered silver sintering, diffusion bond, conductive epoxy, braze, a transient liquid phase bond, nanocopper, or diffusion solder. Each piece of conductive shunt 541 or 542 can be, or can include, a thin conductive material, e.g., a thin metal plate, e.g., a Cu sheet, with good electrical and thermal conductivity. In another embodiment, each conductive shunt 541 or 542 is configured to form contacts with four TE legs associated with two TE unicouples 501 or 502 (each having two redundant TE legs). In yet another embodiment, each conductive shunt 541 or 542 is configured to form contacts with eight TE legs associated with two TE unicouples (each having four redundant TE legs). In an alternative embodiment, the plurality of conductive shunts 541, 542, . . . are held together via a flexible substrate 550 and installed as a whole piece with each conductive shunt being aligned to corresponding two or four TE legs of the MLP 500. In some embodiments, flexible substrate 550 is a good electrical insulator so that each conductive shunt is substantially electrically isolated from all other conductive shunts held on the same flexible substrate.

In the exemplary embodiment shown in FIG. 1, the flexible substrate 550 is substantially disposed between the plurality of conductive shunts 541, 542, . . . and the TE legs 520, 521, . . . so that all the conductive shunts are fully exposed for forming thermal contacts with a second heat source or sink, e.g., (cold-side) heat exchanger (not shown). For example, flexible substrate 550 can include a plurality of apertures defined therethrough, and conductive shunts 541, 542 and the TE legs 520, 521, . . . can be in electrical communication with one another via thermal and electrical paths passing through the apertures. Flexible substrate 500 can be substantially out of the thermal and electrical paths, and accordingly can support conductive shunts 541, 542, . . . substantially without increasing the thermal or electrical resistance of the paths through the apertures. Additionally, conductive shunts 541, 542 can be disposed between flexible substrate 550 and the second heat source or sink, e.g., (cold side) heat exchanger (not shown), such that flexible substrate 550 substantially does not impede thermal transport between the second heat source or sink and the plurality of conductive shunts 541, 542. In a specific embodiment, the flexible substrate 550 is, or includes, a polyimide (also referred to by the trade name KAPTON® and commercially available from E. I. du Pont de Nemours and Company, Wilmington, Del.) film used as a lead frame for supporting the plurality of conductive shunts. In some embodiments, the lead frame (flexible substrate 550) includes apertures or open holes at the end regions of TE legs so that each conductive shunt is directly in contact with the TE legs when the flexible substrate 550 is disposed in the MLP 500. In some embodiments, remaining regions of the flexible substrate 550, e.g., polyimide film, between TE legs are fully connected as a single piece of polyimide film across surface area of the MLP 500. The flexible substrate 550, e.g., polyimide film, because of its poor thermal conductivity (k=0.12 W/m K), provides a natural thermal shield that substantially reduces thermal flux losses due to radiation, convection and conduction through open space between the plurality of TE legs from the hot side to the cold side of the MLP 500. Additionally, polyimide has a high dielectric strength, a high coefficient of thermal expansion (about 200 ppm/° C.), and a high temperature rating. Illustratively, the CTE (coefficient of thermal expansion) on the cold side (e.g., associated with the second heat source or sink to which the conductive shunts can be coupled) can be selected so as to be higher than the CTE on the hot side, such that thermal expansion associated with the second heat source or sink, e.g., on the cold side, potentially can match, or approximately, match, the thermal expansion associated with the first heat source or sink to which the base plate 510 can be coupled, e.g., on the hot side.

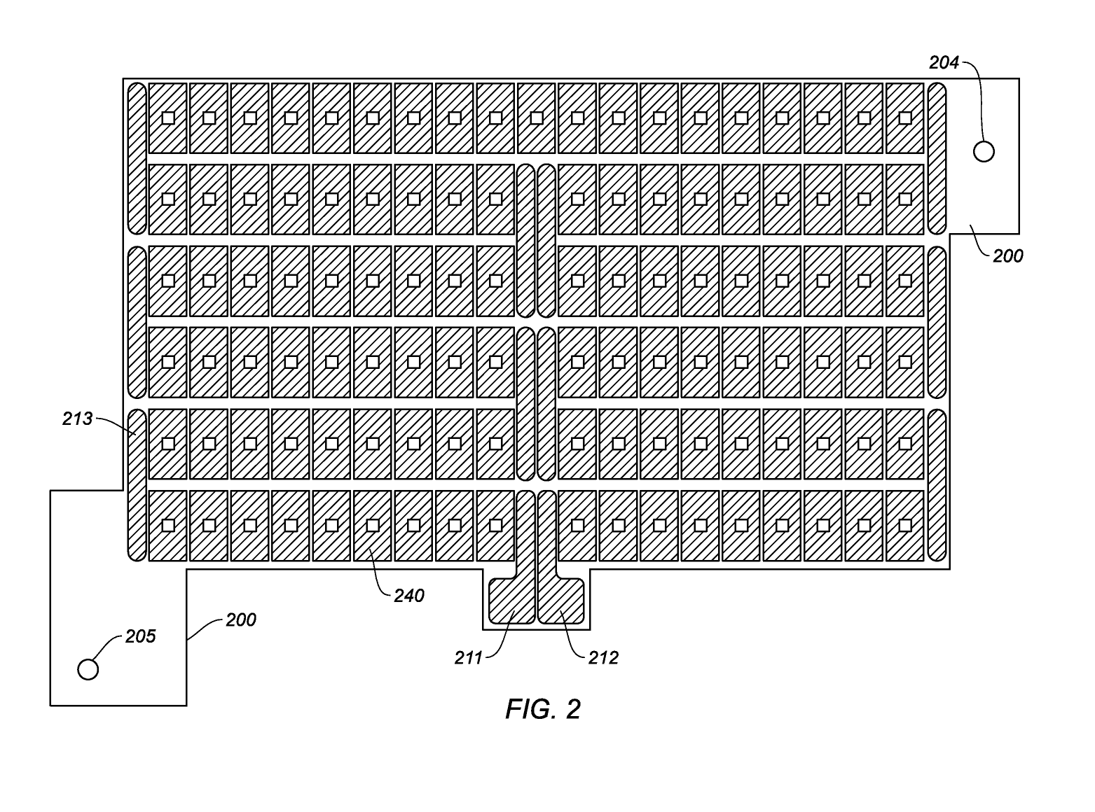

FIG. 2 is a simplified diagram showing a top view of an exemplary, flexible lead frame for a MLP for forming a thermoelectric module, according to one embodiment of the present invention. This diagram is merely an example, which should not unduly limit the scope of the claims. One of ordinary skill in the art would recognize many variations, alternatives, and modifications. As shown, the flexible lead frame 200 is configured to support a plurality of metal shunts 240 arranged in multiple rows and columns, one or more (e.g., a few more) interconnect shunts 213, and one or more (e.g., a pair of) external connection shunts 211 and 212. In an embodiment, the flexible lead frame 200 includes, or is made of, a polyimide film that is defined, e.g., cut by laser, so as to have a specific shape. In some embodiments, a metal film is laminated over one side of the flexible lead frame 200, e.g., polyimide film, and then the metal film is etched so as to form or define the patterned conductive shunts 240 and those interconnect shunts 213 and external connection shunts 211 and 212. In one illustrative embodiment, the polyimide film can have a thickness of about 0.1 mm or less. In another illustrative embodiment, the polyimide film can have a thickness of about 0.2 mm or less. In another illustrative embodiment, the polyimide film can have a thickness of about 0.5 mm or less. In another illustrative embodiment, the metal film can have a thickness of about 0.2 mm or less. In another illustrative embodiment, the metal film can have a thickness of about 0.5 or less.

In a specific embodiment, the flexible lead frame 200, e.g., polyimide film, includes, or is substantially, a flexible substrate, e.g., flexible substrate 500 illustrated in FIG. 1. Each etched region of metal film 240 includes, or is substantially the same as, one of the plurality of conductive shunts 541 illustrated in FIG. 1. In another specific embodiment, the flexible lead frame 200, e.g., polyimide film, includes one or more corner regions including one or more holes defined therein, e.g., one or two corner regions respectively having two holes 204 and 205 in the illustrative embodiment of FIG. 2, which corner regions and holes can be used for alignment convenience when assembling the flexible lead frame 200, e.g., polyimide film, as a lead frame to form a MLP (e.g., MLP 500 in FIG. 1) in a process to manufacture a thermoelectric module. At a protruded region, which in some embodiments is near the middle of the flexible lead frame, e.g., polyimide film, a pair of external connection shunts 211 and 212 can be provided so as to serve for an electrical output (or input) of the Seebeck (or Peltier) type of thermoelectric module. In an alternative embodiment, the flexible lead frame 200, e.g., polyimide film, can be provided in any custom shape to accommodate a predetermined design of the thermoelectric module that is adaptive to a custom shaped heat source. Accordingly, the layout pattern of the conductive shunts and interconnect shunts suitably can be varied.

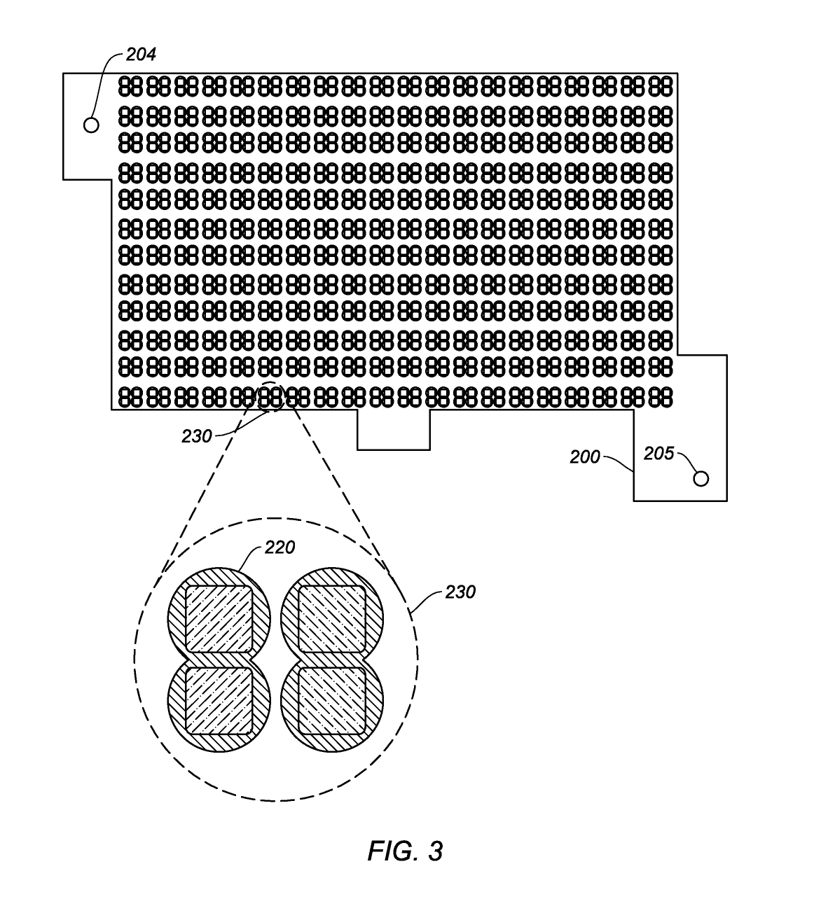

FIG. 3 is a simplified diagram showing a bottom view of the exemplary flexible lead frame shown in FIG. 2 for a MLP for forming a thermoelectric module, according to one embodiment of the present invention. This diagram is merely an example, which should not unduly limit the scope of the claims. One of ordinary skill in the art would recognize many variations, alternatives, and modifications. In the illustrated embodiment, the bottom side of the flexible lead frame 200 is configured to be engaged with a plurality of TE legs pre-installed in a MLP (for example, the MLP 500 shown in FIG. 1). For example, the TE legs can be coupled to a base plate that is configured to be coupled to a first heat source or sink, e.g., a hot side heat source. In a specific embodiment, the plurality of TE legs is arranged in multiple rows and columns of groups 230 of four legs. Around each group 230, the flexible lead frame 200, e.g., polyimide film, is shaped, e.g., is cut, so as to define a pair of dumbbell shaped holes or apertures 220 respectively configured to be disposed over end regions of two pair of TE legs. Thus, the end regions of these TE legs can be bonded with the exposed conductive shunt material on the top side of the flexible lead frame 200, e.g., polyimide film. For example, the conductive shunt material can be configured to be coupled to a second heat source or sink, e.g., a cold side heat sink, such that the conductive shunts are disposed between the flexible substrate (lead frame) and the second heat source or sink such that the flexible substrate substantially does not impede thermal transport between the second heat source or sink and the conductive shunts. In a specific embodiment, one pair of TE legs can be n-type TE legs, and another pair of TE legs are p-type TE legs. In some embodiments, using a plurality of legs, e.g., a group of four legs such as illustrated in FIG. 3, not only adds redundancy to the thermoelectric unicouples in contact with one of the conductive shunts 240 (FIG. 2) but also adds flexibility in passing thermal flow through all the redundant TE unicouples. In yet another specific embodiment, two groups of four TE legs in the column direction are forming four redundant TE unicouples. It should be appreciated that any suitable number of N-type and P-type TE legs can be in thermal and electrical communication with a conductive shunt via any suitable number of apertures. In one example, the plurality of TE legs includes an N-type TE leg and a P-type TE leg, and a conductive shunt is in thermal and electrical communication with the N-type TE leg and the P-type TE leg. The conductive shunt can be in thermal and electrical communication with the N-type TE leg via a first aperture, and the conductive shunt can be in thermal and electrical communication with the P-type TE leg via a second aperture that is the same as, or that is different than, the first aperture.

In an embodiment, the lead frame design in FIG. 2 and FIG. 3 shows a flexible lead frame 200, e.g., polyimide substrate, with apertures or holes through which the TE legs (such as legs 520, 521 in FIG. 1) are bonded to the conductive shunts 240 or metal interconnects 213 including two external connections 211 and 212. Thus, without, or substantially without, any polyimide film material directly between the conductive shunts and the TE legs or between the conductive shunts and the second heat source or sink, e.g., cold side heat sink, a high conductance electrical flow and heat flow path is established from the hot source to the cold sink via the base plate, conductive pads, the TE legs, and the conductive shunts. In a specific embodiment, the flexible lead frame enables the use of these polyimide substrates substantially without a loss in Carnot efficiency. For example, because polyimide substrates have poor thermal conductivity, they can reduce the thermal losses due to convection and conduction from the hot side to the cold side of the TE package. In another specific embodiment, the flexible lead frame, e.g., polyimide film, can also be coated with a conductive material, e.g., metal, e.g., aluminum, within those regions between the TE legs to reduce their emissivity and to reduce or minimize radiation losses.

In some embodiments, by disposing the conductive shunts between the flexible substrate and the second heat source or sink, e.g., cold side heat sink, so as to expose the shunts above the flexible lead frame, e.g., polyimide film, to form thermal contact with the cold-side heat sink (e.g., exchanger), an additional dielectric layer can be used, and in some circumstances is required, to provide electrical isolation between the cold heat exchanger and top surface of the shunts. This dielectric, for example, can be, or can include, an anodized layer on an aluminum cold heat exchanger.

It should be appreciated that the present flexible lead frames suitably may be used in a variety of configurations. For example, in some embodiments, a pattern (layout) of conductive shunts (which also may be referred to as traces or conductors), e.g., copper shunts, can be configured so as to connect adjacent TE legs of different material types. It can be useful to define the apertures through the flexible substrates based on the particular material types used for the P-type or N-type legs. For example, the apertures can be defined so as to provide different cross-sectional area ratios (or different aspect ratios (A/L) for the P-type legs as compared to for the N-type legs in order to enhance, e.g., maximize, the performance of the TE device. For example, because the P- and N-type TE materials can have different thermoelectric properties (e.g., Seebeck coefficient, electrical resistivity, and thermal conductivity), there can be compatibility mismatch between the materials that otherwise potentially can cause the TE device to operate sub-optimally. For example, in one nonlimiting embodiment, P-type TE legs can include tetrahedrite, and N-type TE legs can include magnesium silicide. Adjusting the size and shape of the apertures, e.g., the cross-sectional area, can help to combat such differences in the thermoelectric properties of the P- and N-type TE materials. The TE leg length can also be adjusted to combat incompatibility between materials.

In one embodiment, an exemplary layout of shunts is for a thermoelectric device wherein each couple includes two TE legs—one monolithic piece of P type and one of N type, so as to achieve a specific ratio of P-type to N-type material within the couple or junction. Such a layout can accommodate a range of P-type to N-type ratios within a single couple or junction. The position and size of the aperture or apertures can be selected so as to adjust the area of conductive shunt exposed by the aperture. For example, the respective size and location of the P-type and N-type TE legs can be adjusted so as to suitably increase or decrease the footprint of the single N-type element and so as to suitably increase or decrease the footprint of the single P-type leg.

In embodiments in which the plurality of thermoelectric legs includes a plurality of N-type thermoelectric legs having a first area and a plurality of P-type thermoelectric legs having a second area, a pattern of the apertures can selected so as to maximize a packing fraction of the thermoelectric legs and so as to optimize a ratio of the first area to the second area. Optionally, each N-type thermoelectric leg has a first aspect ratio and each of the P-type thermoelectric legs has a second aspect ratio, the pattern of the apertures further being selected so as to optimize a ratio of the first aspect ratio to the second aspect ratio.

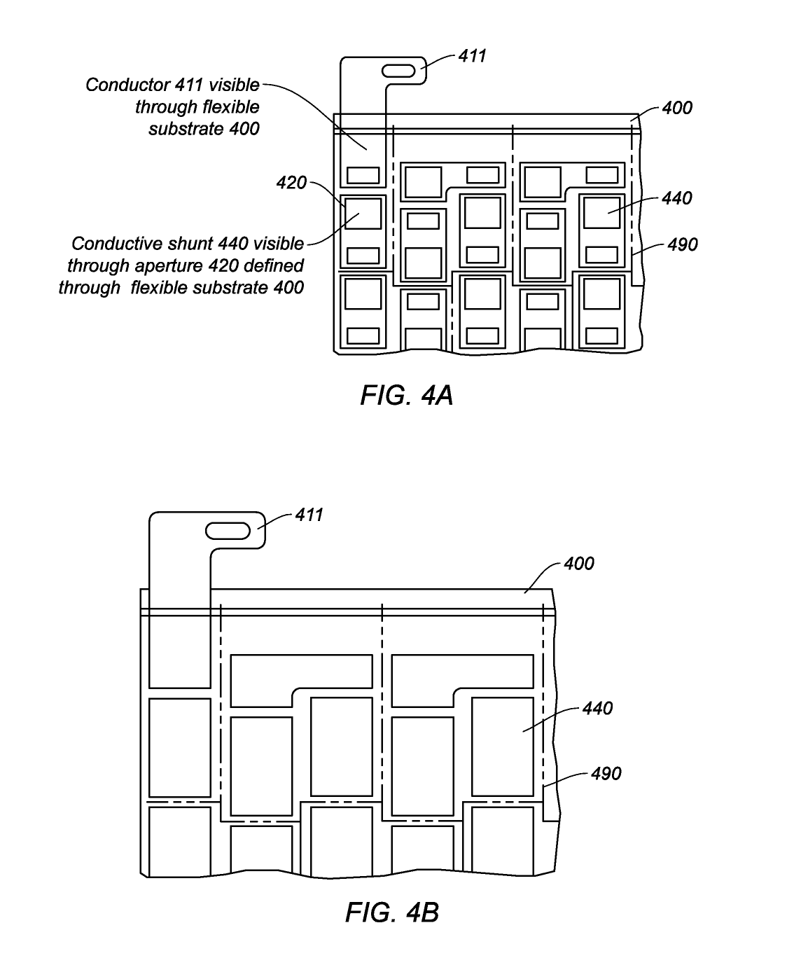

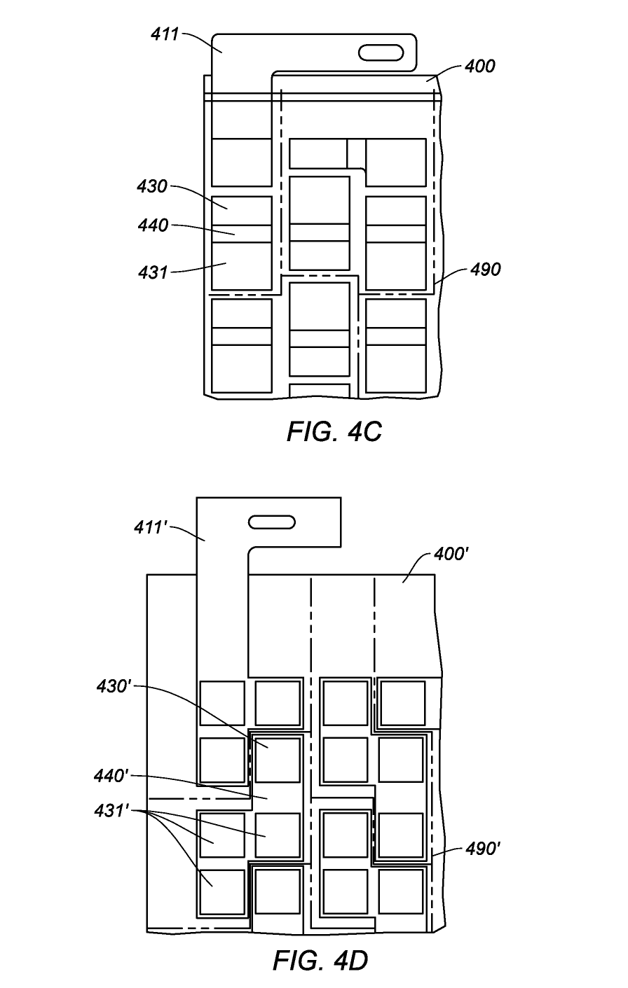

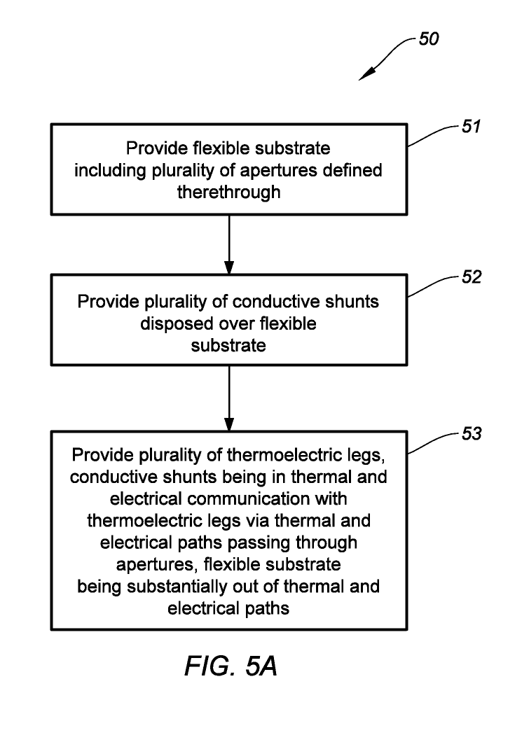

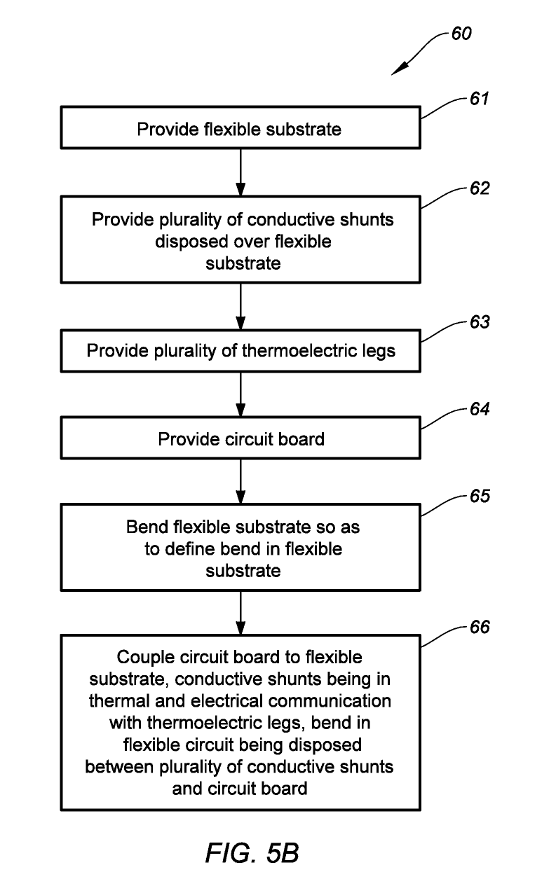

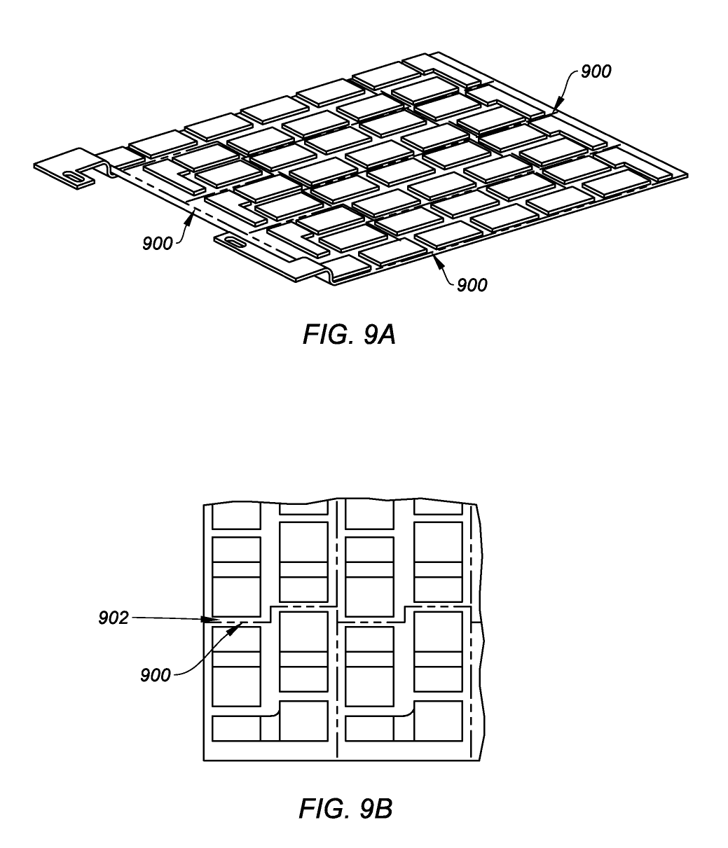

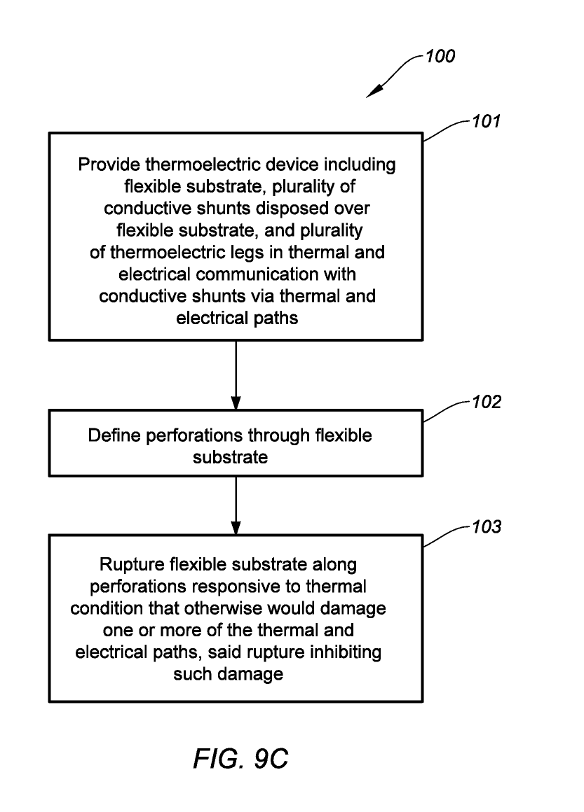

In one example, FIGS. 4A-4D are simplified diagrams showing alternative exemplary, flexible lead frames for a MLP for forming a thermoelectric module, according to one exemplary embodiment of the present invention. These diagrams are merely an example, which should not unduly limit the scope of the claims. One of ordinary skill in the art would recognize many variations, alternatives, and modifications. FIG. 4A illustrates a top view of an exemplary layout of conductive shunts 440 disposed over a bottom surface of flexible substrate 400 relative to apertures 420 defined through substrate 400. Additionally, conductor 411 is partially disposed over the back surface of flexible substrate 400 and partially extends past flexible substrate 400 so as to facilitate connection of the MLP to an external electrical device (not illustrated). It can be seen that conductive shunts 440 and conductor 411 are visible through apertures 420 defined through flexible substrate 400. Additionally, flexible substrate 400 is shown in partial transparency so that the layout of conductive shunts 440 and conductor 411 can be seen relative to one another and relative to apertures 420. It should be understood that substrate 400 can be at least partially transparent, or can be fully or partially opaque. FIG. 4B illustrates a bottom view of the exemplary layout of conductive shunts 440 and conductor 411 of FIG. 4A disposed on the bottom surface of flexible substrate 400, in which shunts 440 and conductor 411 obscure apertures 420. FIG. 4C illustrates a top view of the exemplary layout of conductive shunts 440 and conductor 411 relative to apertures 420 (which can be located where legs 430 and 431 are shown) defined through flexible substrate 400 of FIG. 4A, and that also includes N-type TE legs 430 and P-type TE legs 431 that are in thermal and electrical communication with conductive shunts 440 via apertures 420 via thermal and electrical paths passing through apertures 420. Optionally, the assembly illustrated in FIGS. 4A-4C can be coupled to a circuit board via a bend in the flexible substrate in a manner such as described below with reference to FIGS. 5B and 7A-8C. Additionally, or alternatively, the assembly illustrated in FIGS. 4A-4C optionally can include perforations 490 that are configured to rupture responsive to a temperature condition that otherwise would damage one or more thermal and electrical paths between TE legs 430, 431 and conductive shunts 440, said rupture inhibiting such damage in a manner such as described below with reference to FIGS. 9A-9C.

In some embodiments, the thermoelectric structure further illustrated in FIGS. 4A-4C is configured to be coupled to a first heat source or sink and to a second heat source or sink. The thermoelectric structure illustrated in FIGS. 4A-4C further can include a base plate coupled to at least a subset of the plurality of conductive legs and to the first heat source or sink. The plurality of conductive shunts illustrated in FIGS. 4A-4C can be coupled to the second heat source or sink, the plurality of conductive shunts being disposed between the flexible substrate and the second heat source or sink such that the flexible substrate substantially does not impede thermal transport between the second heat source or sink and the plurality of conductive shunts.

An alternate layout of shunts also can be used for couples wherein one or both of the TE material types are not monolithic and are split into multiple pieces within a single couple or junction. In some embodiments, this design can allow for all thermoelectric elements to have the same dimensions as one another, while still achieving ratios of P-type to N-type other than unity. This layout also can allow for all thermoelectric elements to be square, e.g., so as to reduce or minimize the number of unique dimensions required for the dicing process. For example, FIG. 4D illustrates a top view of an embodiment including an exemplary layout of conductive shunts 440′ disposed over a bottom surface of flexible substrate 400′ relative to apertures 420′ defined through substrate 400′. Additionally, conductor 411′ is partially disposed over the back surface of flexible substrate 400′ and partially extends past flexible substrate 400′ so as to facilitate connection of the MLP to an external electrical device (not illustrated). It can be seen that conductive shunts 440′ and conductor 411′ are visible through apertures 420 (which can be located where legs 430′ and 431′ are shown) defined through flexible substrate 400′. Additionally, flexible substrate 400′ is shown in partial transparency so that the layout of conductive shunts 440′ and conductor 411′ can be seen relative to one another and relative to apertures 420′. It should be understood that substrate 400′ can be at least partially transparent, or can be fully or partially opaque. Additionally, FIG. 4D illustrates N-type TE legs 430′ and P-type TE legs 431′ that are in thermal and electrical communication with conductive shunts 440′ via apertures 420′ via thermal and electrical paths passing through apertures 420′. In one example, the plurality of thermoelectric legs includes an N-type thermoelectric leg and two or more P-type thermoelectric legs (e.g., three), a conductive shunt 440′ being in thermal and electrical communication with the N-type thermoelectric leg and with the two or more P-type thermoelectric legs (e.g., three). Illustratively, the conductive shunt 440′ can be in thermal and electrical communication with the N-type thermoelectric leg 430′ via a first aperture, and the conductive shunt 440′ can be in thermal and electrical communication with each of the two more P-type thermoelectric legs (e.g., three) via corresponding apertures that are different than the first aperture. Or, for example, the plurality of thermoelectric legs can include two or more N-type thermoelectric legs and a P-type thermoelectric leg, and a conductive shunt can be placed in thermal and electrical communication with the two or more N-type thermoelectric legs and with the P-type thermoelectric leg. For example, the conductive shunt can be in thermal and electrical communication with each of the two or more N-type thermoelectric legs via one or more first apertures, and the conductive shunt can be placed in thermal and electrical communication with the P-type thermoelectric leg via a corresponding aperture that is different than the first apertures.

Optionally, the assembly illustrated in FIG. 4D can be coupled to a circuit board via a bend in the flexible substrate in a manner such as described below with reference to FIGS. 5B and 7A-8C. Additionally, or alternatively, the assembly illustrated in FIG. 4D optionally can include perforations 490′ that are configured to rupture responsive to a temperature condition that otherwise would damage one or more thermal and electrical paths between TE legs 430′,431′ and conductive shunts 440, said rupture inhibiting such damage in a manner such as described below with reference to FIGS. 9A-9C.

In some embodiments, the thermoelectric structure illustrated in FIG. 4D further is configured to be coupled to a first heat source or sink and to a second heat source or sink. The thermoelectric structure illustrated in FIG. 4D further can include a base plate coupled to at least a subset of the plurality of conductive legs and to the first heat source or sink. The plurality of conductive shunts illustrated in FIG. 4D can be coupled to the second heat source or sink, the plurality of conductive shunts being disposed between the flexible substrate and the second heat source or sink such that the flexible substrate substantially does not impede thermal transport between the second heat source or sink and the plurality of conductive shunts.

FIG. 5A illustrates an exemplary method for forming a MLP for forming a thermoelectric module including a flexible lead frame, according to one exemplary embodiment of the present invention. This diagram is merely an example, which should not unduly limit the scope of the claims. One of ordinary skill in the art would recognize many variations, alternatives, and modifications.

Exemplary method 50 illustrated in FIG. 5A includes providing a flexible substrate including a plurality of apertures defined therethrough (51). Illustratively, the flexible substrate can include, can consist essentially of, or can be, polyimide (commercially available under trade name KAPTON® and commercially available from E. I. du Pont de Nemours and Company, Wilmington, Del.). Method 50 can include defining the apertures through the flexible substrate via any suitable method. For example, the apertures can be cut through the substrate, e.g., using laser cutting, mechanical cutting, or the like. Alternatively, the apertures can be defined through the flexible substrate at the time of forming the substrate, thus obviating the need for a separate cutting step. Any suitable pattern of apertures can be suitably defined through the flexible substrate. Some nonlimiting, purely illustrative patterns of apertures are described further above with reference to FIGS. 1-4D.

Exemplary method 50 illustrated in FIG. 5A further includes providing a plurality of conductive shunts disposed over the flexible substrate (52). Illustratively, the plurality of conductive shunts can be disposed over the flexible substrate using any suitable deposition process known in the art or yet to be developed. For example, a layer of conductive material, e.g., a metal, e.g., copper, aluminum, CuMo alloy, or different Cu alloys, can be disposed over the flexible substrate using any suitable deposition technique (e.g., electrodeposition, physical vapor deposition, chemical vapor deposition, and the like) and subsequently patterned (e.g., using photolithography and wet etching or dry etching). As another example, a patterned layer of conductive material, e.g., a metal, e.g., copper, can be deposited over the flexible substrate technique using any suitable deposition technique (e.g., masking coupled with a suitable deposition technique such as physical vapor deposition or chemical vapor deposition), thus obviating the need for a separate patterning step. As yet another example, the conductive shunts can be formed as a physically separate object and can be placed over the apertures through the flexible substrate prior to, or at the time of, assembling the MLP and suitably coupled to, e.g., soldered, silver sintered, diffusion bonded, bonded with conductive epoxy, brazed, transient liquid phase bonded, bonded with nanocopper, or diffusion soldered, to the TE legs through the apertures in the substrate. Illustratively, the conductive shunts can coupled to the flexible substrate using a suitable adhesive. Note that the conductive shunts can be disposed over the flexible substrate, and the apertures can be defined through the flexible substrate, in any suitable order. For example, the conductive shunts can be disposed over the flexible substrate before the apertures are defined, or the conductive shunts can be disposed over the flexible substrate after the apertures are defined.

Method 50 illustrated in FIG. 5A further includes providing a plurality of thermoelectric legs, the conductive shunts being in thermal and electrical communication with the thermoelectric legs via thermal and electrical paths passing through the apertures, the flexible substrate being substantially out of the thermal and electrical paths (53). For example, a plurality of TE legs can be defined on a base plate analogously as described above with reference to FIGS. 1-3 or as known in the art. The flexible substrate can be disposed over the plurality of thermoelectric legs, e.g., such that one or more apertures disposed through the substrate respectively are substantially aligned over one or more corresponding thermoelectric legs.

In some embodiments, a given aperture can have a cross-sectional area that is approximately 10% or more of the cross-sectional area of the TE leg over which that aperture is aligned. In some embodiments, a given aperture can have a cross-sectional area that is approximately 20% or more of the cross-sectional area of the TE leg over which that aperture is aligned. In some embodiments, a given aperture can have a cross-sectional area that is approximately 30% or more of the cross-sectional area of the TE leg over which that aperture is aligned. In some embodiments, a given aperture can have a cross-sectional area that is approximately 40% or more of the cross-sectional area of the TE leg over which that aperture is aligned. In some embodiments, a given aperture can have a cross-sectional area that is approximately 50% or more of the cross-sectional area of the TE leg over which that aperture is aligned. In some embodiments, a given aperture can have a cross-sectional area that is approximately 60% or more of the cross-sectional area of the TE leg over which that aperture is aligned. In some embodiments, a given aperture can have a cross-sectional area that is approximately 70% or more of the cross-sectional area of the TE leg over which that aperture is aligned. In some embodiments, a given aperture can have a cross-sectional area that is approximately 80% or more of the cross-sectional area of the TE leg over which that aperture is aligned. In some embodiments, a given aperture can have a cross-sectional area that is approximately 90% or more of the cross-sectional area of the TE leg over which that aperture is aligned. In some embodiments, a given aperture can have a cross-sectional area that is approximately 100% or more of the cross-sectional area of the TE leg over which that aperture is aligned. In some embodiments, a given aperture can have a cross-sectional area that is approximately 110% or more of the cross-sectional area of the TE leg over which that aperture is aligned. In some embodiments, a given aperture can have a cross-sectional area that is approximately 120% or more of the cross-sectional area of the TE leg over which that aperture is aligned. In some embodiments, a given aperture can have a cross-sectional area that is approximately 130% or more of the cross-sectional area of the TE leg over which that aperture is aligned. In some embodiments, a given aperture can have a cross-sectional area that is approximately 140% or more of the cross-sectional area of the TE leg over which that aperture is aligned. In some embodiments, a given aperture can have a cross-sectional area that is approximately 150% or more of the cross-sectional area of the TE leg over which that aperture is aligned. In some embodiments, a given aperture can have a cross-sectional area that is approximately 160% or more of the cross-sectional area of the TE leg over which that aperture is aligned. In some embodiments, a given aperture can have a cross-sectional area that is approximately 170% or more of the cross-sectional area of the TE leg over which that aperture is aligned. In some embodiments, a given aperture can have a cross-sectional area that is approximately 180% or more of the cross-sectional area of the TE leg over which that aperture is aligned. In some embodiments, a given aperture can have a cross-sectional area that is approximately 190% or more of the cross-sectional area of the TE leg over which that aperture is aligned. In some embodiments, a given aperture can have a cross-sectional area that is approximately 200% or more of the cross-sectional area of the TE leg over which that aperture is aligned.

Additionally, the plurality of thermoelectric legs can include a plurality of N-type thermoelectric legs having a first area and a plurality of P-type thermoelectric legs having a second area, and method 50 can include selecting a pattern of the apertures so as to maximize a packing fraction of the thermoelectric legs and so as to optimize a ratio of the first area to the second area. Optionally, each N-type thermoelectric leg has a first aspect ratio and wherein each the P-type thermoelectric leg has a second aspect ratio, and method 50 further can include selecting the pattern of the apertures so as to optimize a ratio of the first aspect ratio to the second aspect ratio.

The conductive shunts can be brought into thermal and electrical communication with one or more of the TE legs via the apertures via any suitable technique, and in any suitable order. For example, the conductive shunts can be disposed over the flexible substrate before the flexible substrate is disposed over the plurality of TE legs, or the conductive shunts can be disposed over the flexible substrate after the flexible substrate is disposed over the plurality of TE legs. For example, in some embodiments, the conductive shunts can be disposed over the flexible substrate prior to the flexible substrate being disposed over the plurality of TE legs, and can be thermally and electrically coupled to the TE legs through the apertures using any suitable technique, e.g., soldering. As another example, in some embodiments, the conductive shunts can be disposed over the flexible substrate after the flexible substrate is disposed over the plurality of TE legs, and can be thermally and electrically coupled to the TE legs through the apertures using any suitable technique, e.g., soldering, silver sintering, diffusion bonding, conductive epoxy, brazing, transient liquid phase bonding, nanocopper, or diffusion solder.

In some embodiments, method 50 further includes coupling the resulting thermoelectric structure to a first heat source or sink and to a second heat source or sink. Method 50 further can include coupling a base plate to at least a subset of the plurality of conductive legs and to the first heat source or sink. Method 50 further can include coupling the plurality of conductive shunts to the second heat source or sink such that the plurality of conductive shunts are disposed between the flexible substrate and the second heat source or sink such that the flexible substrate substantially does not impede thermal transport between the second heat source or sink and the plurality of conductive shunts.

In some embodiments, method 50 further includes coupling the plurality of thermoelectric legs to a base plate and defining a notch in the base plate so as to partially relieve thermal stress and allow a small degree of bending flexibility

Note that any suitable number, type, and pattern of TE legs and thermoelectric shunts can be coupled to one another through apertures through a flexible substrate using method 50 illustrated in FIG. 5A. For example, the plurality of thermoelectric legs can include an N-type thermoelectric leg and a P-type thermoelectric leg, and the method can include placing a conductive shunt in thermal and electrical communication with the N-type thermoelectric leg and with the P-type thermoelectric leg. Illustratively, the method can include placing the conductive shunt in thermal and electrical communication with the N-type thermoelectric leg via a first aperture, and placing the conductive shunt in thermal and electrical communication with the P-type thermoelectric leg via a second aperture that is different than the first aperture. Or, for example, the plurality of thermoelectric legs can include an N-type thermoelectric leg and two or more P-type thermoelectric legs, and the method can include placing a conductive shunt in thermal and electrical communication with the N-type thermoelectric leg and with the two or more P-type thermoelectric legs. Illustratively, the method can include placing the conductive shunt in thermal and electrical communication with the N-type thermoelectric leg via a first aperture, and placing the conductive shunt in thermal and electrical communication with each of the two or more P-type thermoelectric legs via corresponding apertures that are different than the first aperture. Or, for example, the plurality of thermoelectric legs can include two or more N-type thermoelectric legs and a P-type thermoelectric leg, and the method can include placing a conductive shunt in thermal and electrical communication with the two or more N-type thermoelectric legs and with the P-type thermoelectric leg. Illustratively, the method can include placing the conductive shunt in thermal and electrical communication with the two or more N-type thermoelectric legs via one or more corresponding first apertures, and placing the conductive shunt in thermal and electrical communication with the P-type thermoelectric leg via a corresponding aperture that is different than the first apertures.

Additionally, or alternatively, method 50 illustrated in FIG. 5A optionally can include coupling a circuit board to the flexible substrate and defining a bend in the flexible substrate, the bend being disposed between the plurality of conductive shunts and the circuit board, in a manner such as described below with reference to FIGS. 5B and 7A-8C. Additionally, or alternatively, method 50 illustrated in FIG. 5A optionally can include defining through the flexible substrate a plurality of perforations, the perforations being configured to rupture responsive to a temperature condition that otherwise would damage one or more of the thermal and electrical paths, said rupture inhibiting such damage, in a manner such as described below with reference to FIGS. 9A-9C.

As noted above, in some embodiments, MLPs including a flexible lead frame such as described herein can be integrated onto a large circuit board during assembly. However, such integration can add a mechanical constraint and therefore a potential source of thermomechanical stress during operation of the resulting device. In some embodiments, the addition of a flexible or compliant connection between the MLP and the circuit board can be provided so as to inhibit possible failure due to integration and operation. For example, in some embodiments, a thermoelectric structure includes a flexible substrate; a plurality of conductive shunts disposed over the flexible substrate; a plurality of thermoelectric legs; and a circuit board coupled to the flexible substrate. The conductive shunts can be in thermal and electrical communication with the thermoelectric legs, and a bend in the flexible substrate can be disposed between the plurality of conductive shunts and the circuit board. In some embodiments, the thermoelectric structure further is configured to be coupled to a first heat source or sink and to a second heat source or sink. The thermoelectric structure further can include a base plate coupled to at least a subset of the plurality of conductive legs and to the first heat source or sink. The plurality of conductive shunts can be coupled to the second heat source or sink, the plurality of conductive shunts being disposed between the flexible substrate and the second heat source or sink such that the flexible substrate substantially does not impede thermal transport between the second heat source or sink and the plurality of conductive shunts.

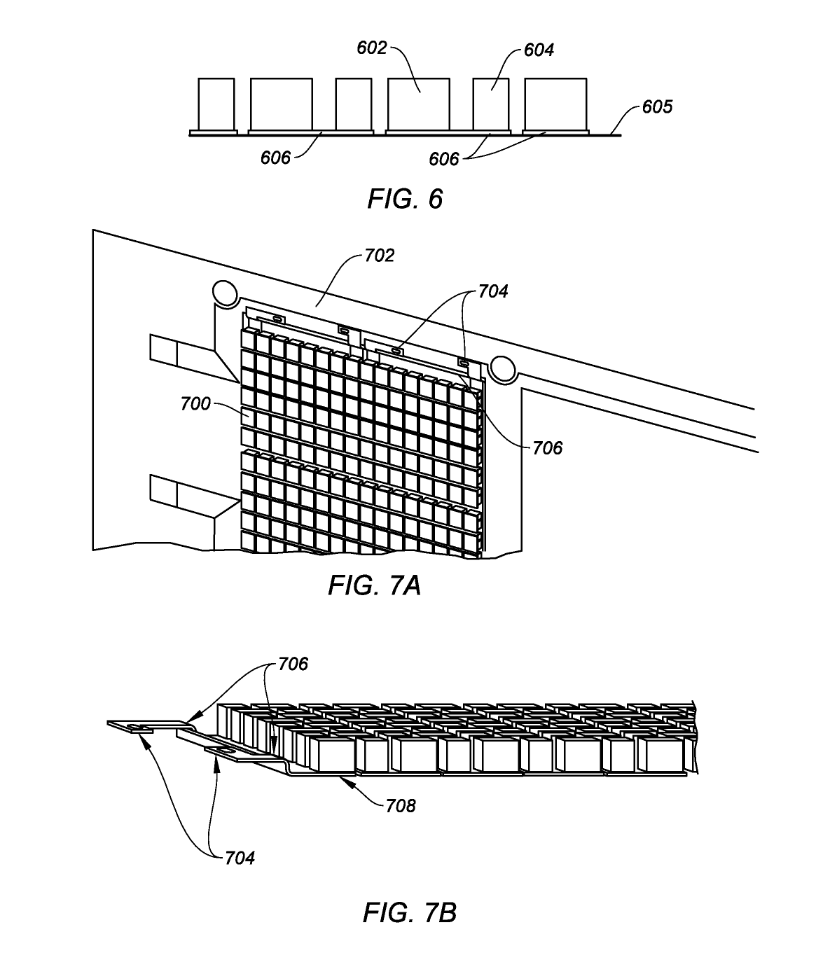

For example, FIGS. 7A-7B are simplified diagrams showing alternative exemplary, flexible lead frames for a MLP for forming a thermoelectric module, according to one exemplary embodiment of the present invention. These diagrams are merely an example, which should not unduly limit the scope of the claims. One of ordinary skill in the art would recognize many variations, alternatives, and modifications. In the embodiment illustrated in FIG. 7A, MLP 700 includes a flexible substrate, a plurality of conductive shunts disposed over the flexible substrate, and a plurality of thermoelectric legs, which suitably can be arranged analogously as described elsewhere herein. As illustrated in FIG. 7A, MLP 700 can be coupled to circuit board 702 via bend 706, e.g., an s-bend and one or more electrical lead solder joints. FIG. 7B illustrates greater detail of MLP 700, including the intermediate location of bend 706 and one or more points of rigid contact 704 to circuit board 702. Bend 706 illustrated in FIGS. 7A-7B can be, but need not necessarily be, an s-bend. As used herein, the term “s-bend” is intended to refer to the general shape of the bend 706 that can be defined in the flexible substrate of the MLP. The s-bend can define a double-bend (which also can be referred to as a “z-bend”) that acts analogously to a spring, e.g., can bend and give without necessarily causing plastic deformation of the conductive shunts, e.g., copper shunts. In some embodiments, the bend 706, e.g., s-bend, can be located between the rigid joint 708 and contacts 704 of the flexible lead frame and other materials in the device, specifically the thermoelectric legs. The bend 706, e.g., s-bend, placement and shape can be selected so as to predictably control any relative motion of the MLP 700 and the circuit board 702. It should be appreciated that any other shapes of bends suitably can be used.

An MLP and a circuit board, e.g., MLP 700 and circuit board 702 illustrated in FIGS. 7A-7B, suitably can be coupled to one another via a bend, e.g., via an s-bend, using any suitable method. For example, FIG. 5B illustrates an exemplary method for forming a MLP for forming a thermoelectric module including a flexible lead frame, according to one exemplary embodiment of the present invention. This diagram is merely an example, which should not unduly limit the scope of the claims. One of ordinary skill in the art would recognize many variations, alternatives, and modifications. Method 60 illustrated in FIG. 5B includes providing a flexible substrate (61), providing a plurality of conductive shunts disposed over the flexible substrate (62), and providing a plurality of thermoelectric legs (63). Steps for providing such elements are described in greater detail elsewhere herein. For example, method 60 can include providing MLP 700 illustrated in FIGS. 7A-7B.

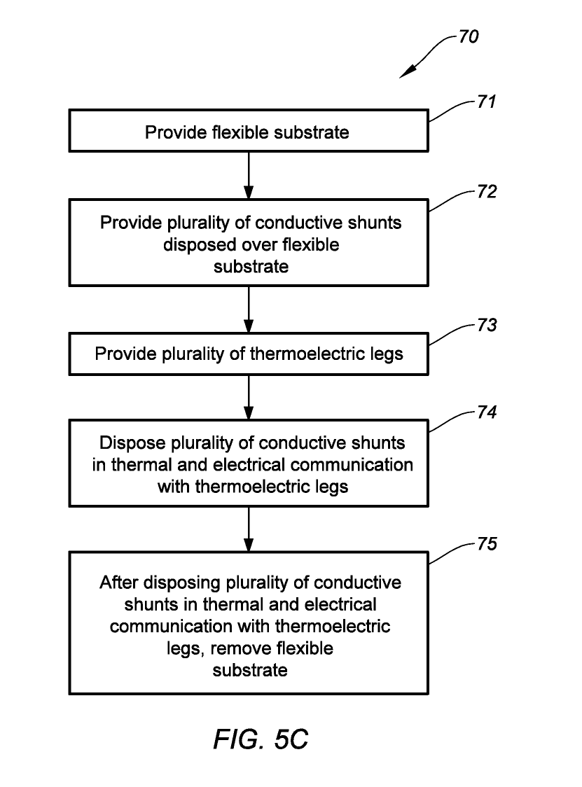

Method 60 illustrated in FIG. 5B further includes providing a circuit board (64). For example, method 60 can include providing circuit board 702 illustrated in FIG. 6. The circuit board can be used to connect multiple MLPs together using more than wires alone. The positive and negative leads (411) from an MLP can connect to copper pads on the circuit board. A bend, such as an s-bend, can provide some flexibility in this connection and/or can help to make up for any height differences between the MLP and the circuit board such that the leads can be connected on top of the circuit board as opposed to on the bottom of the circuit board.

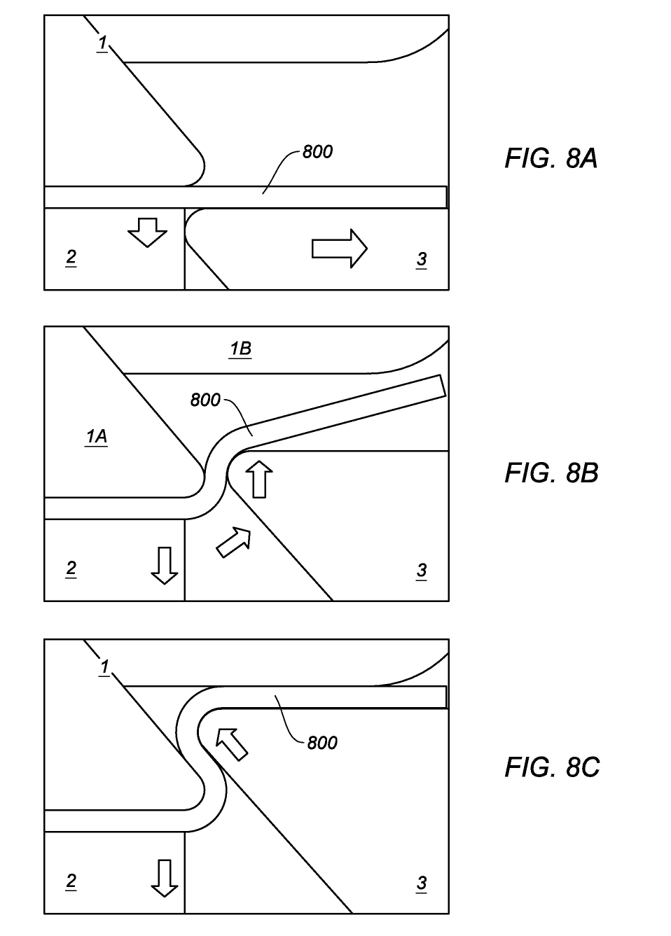

Method 60 illustrated in FIG. 5B further includes bending the flexible substrate so as to define a bend in the flexible substrate. Illustratively, the bend can include an s-bend such as described further above, or can have any other suitable shape. The bend can be defined using any suitable method. For example, FIGS. 8A-8B illustrate exemplary structures formed during a method for coupling a flexible lead frame to a circuit board, according to one exemplary embodiment of the present invention. These diagrams are merely an example, which should not unduly limit the scope of the claims. One of ordinary skill in the art would recognize many variations, alternatives, and modifications. In the non-limiting embodiment illustrated in FIG. 8A, flexible substrate 800 suitably is arranged relative to three pieces of tooling, respectively designated 1, 2, and 3. More specifically, flexible substrate 800 initially is securely held between a lower surface of first piece of tooling 1 and an upper surface of second piece of tooling 2 so as to extend over an upper surface of third piece of tooling 3. Then, as illustrated in FIG. 8B, third piece of tooling 3 is moved upwards while flexible substrate 800 remains securely held between the lower surface of first piece of tooling 1 and the upper surface of second piece of tooling 2 so as to induce one or more bends in flexible substrate 800. For example, first piece of tooling 1 can include a first angled feature 1A against which third piece of tooling forces flexible substrate 800 so as to induce a first bend in flexible substrate 800. Third piece of tooling 3 can include a second angled feature that causes flexible substrate 800 to bend upwards against a third angled feature 1B of first piece of tooling 1, and the combination of forces from the second angled feature and third angled feature 1B induce a second bend in flexible substrate 800 in a reverse direction relative to the first bend. Then, as illustrated in FIG. 8C, third piece of tooling 3 continues to move upwards while flexible substrate 800 remains securely held between the lower surface of first piece of tooling 1 and the upper surface of second piece of tooling 2 so as to further induce one or more bends in flexible substrate 800. For example, first angled feature 1A against which third piece of tooling forces flexible substrate 800 can further induce a first bend in flexible substrate 800, and the combination of forces from the second angled feature and third angled feature 1B can further induce a second bend in flexible substrate 800 in a reverse direction relative to the first bend, thus forming an s-bend. It should be appreciated that other tooling arrangements suitably can be used to define bends of any desired shape in the flexible substrate.

Referring again to FIG. 5B, the circuit board can be coupled to the flexible substrate, the conductive shunts being in thermal and electrical communication with the thermoelectric legs, the bend in the flexible substrate being disposed between the plurality of the conductive shunts and the circuit board (66). Exemplary methods for providing thermal and electrical communication between conductive shunts and thermoelectric legs (optionally through apertures defined through the flexible substrate) are provided elsewhere herein. Exemplary methods for coupling a circuit board to a flexible substrate, such that the bend in the flexible substrate is disposed between the plurality of the conductive shunts and the circuit board, include soldering. For example, MLP 700 illustrated in FIGS. 7A-7B, including bend 706, suitably can be coupled to circuit board 702. In some embodiments, thermoelectric structure 700 further is configured to be coupled to a first heat source or sink and to a second heat source or sink. The thermoelectric structure 700 further can include a base plate coupled to at least a subset of the plurality of conductive legs and to the first heat source or sink. The plurality of conductive shunts can be coupled to the second heat source or sink, the plurality of conductive shunts being disposed between the flexible substrate and the second heat source or sink such that the flexible substrate substantially does not impede thermal transport between the second heat source or sink and the plurality of conductive shunts. Method 60 illustrated in FIG. 5B can include forming such an arrangement.

It should be appreciated that the MLPs provided herein can have any suitable arrangement, and can be made in any suitable manner. For example, FIG. 6 is a simplified diagram showing an alternative exemplary, flexible lead frame for a MLP for forming a thermoelectric module, according to one exemplary embodiment of the present invention. This diagram is merely an example, which should not unduly limit the scope of the claims. One of ordinary skill in the art would recognize many variations, alternatives, and modifications. The flexible lead frame illustrated in FIG. 6 includes a flexible substrate 605 and conductive shunt 606, e.g., copper shunt coupled to the flexible substrate via an adhesive layer. The conductive shunts are coupled to TE legs, e.g., each conductive shunt is coupled to at least one N-type TE leg 602 and to at least one P-type TE leg 604. Additionally, the flexible substrate 605 can be coupled to a cold sink (e.g., the bottom surface of the flexible substrate 605 illustrated in FIG. 6 can be coupled to a cold sink, not specifically illustrated). In various embodiments, the thickness of the flexible lead frame illustrated in FIG. 6 can be defined as the sum of the thickness of the flexible substrate 605, e.g., polyimide layer, the thickness of the conductive shunt 606, e.g., copper shunt, and the thickness of the adhesive layer (if provided, not specifically illustrated) holding the substrate 605 and the conductive shunt 606 together. The thickness of the flexible lead frame can provide a thermal impedance between the cold sink of the system and the cold junction of the device. Reducing, or minimizing, the cold junction temperature can improve the Carnot efficiency and the thermoelectric conversion efficiency of the device, motivating a reduction to, or a minimization of, the thickness of the flexible lead frame. For example, in some embodiments, the design of the flexible lead frame includes a flexible substrate 605, e.g., polyimide layer, as mechanical carrier for individual conductive shunts 606 that electrically bridge a suitable number of TE legs 602, 604, e.g., adjacent TE legs. The thickness of the flexible substrate 605, e.g., polyimide layer, can be thin as manufactured and assembled, and can be configured so as to increase the thermal conductance of the flexible substrate 605 to the extent practicable or possible; when combined these properties can reduce, or even provide a minimal, thermal impedance and thereby can increase, or even provide a maximum, temperature gradient across the thermoelectric device. For example, reducing the thickness of the flexible substrate 605 can increase the thermal conductance or reduce the thermal resistance. In addition, there are different types of polyimide material. Some have higher thermal conductivities than others, such as DuPont™ KAPTON® MT, which is commercially available from E. I. du Pont de Nemours and Company, Wilmington, Del.). Additionally, the conductive shunts 606, e.g., copper shunts, also can provide a thermal impedance, but are of such high thermal conductivity that their design can prioritize electrical resistance and mechanical stress over thermal impedance. Suitable thicknesses of the conductive shunts 606, e.g., copper layer, can be based on the electrical losses that such thicknesses can cause. For example, in some embodiments, the resistance of the conductive shunts 606, e.g., copper shunts, can be limited to a certain percent resistance of the total electrical resistance of the thermoelectric material. Joule heating is the phenomenon by which electrical power is dissipated and lost as heat (thermal power). The conductive shunts 606, e.g., copper shunts, herein can be designed such that their resistance is approximately <5% (preferably <1%) relative to the thermoelectric couples, thus reducing the loss of the thermoelectric power produced by the device.

Additionally, thermomechanical stress can be induced by rigidly bonding materials with disparate mechanical properties and exposing them to temperatures above and below the bonding temperature. The magnitude of the induced stress can be proportional to the differences in both stiffness (a product of geometry and Young's Modulus, which also can be referred to as Elastic Modulus), and Coefficient of Thermal Expansion. The thickness of the conductive shunts can be specifically engineered so as to reduce or minimize stress between the conductive shunt, e.g., copper shunt, and the TE legs, but also can be used to protect the MLP from stresses induced by other materials in the MLP and overall device.

It should be appreciated that the embodiment illustrated in FIG. 6 suitably can be modified by removing the flexible substrate 605, so as to provide a thermoelectric structure that includes a plurality of conductive shunts 606 (e.g., copper shunts), a plurality of thermoelectric legs (e.g., P-type legs 602 and N-type legs 604), wherein the plurality of conductive shunts 606 are in direct thermal and electrical communication with the thermoelectric legs 602, 604 via a conductor. For example, the flexible substrate 605 suitably can be used as a removable carrier for conductive shunts 606 so as to facilitate formation of thermoelectric devices in which the plurality of conductive shunts are in direct thermal and electrical communication with the thermoelectric legs via a conductor. The resulting thermoelectric structure further can include a base plate coupled to at least a subset of the plurality of conductive legs 602, 604 and to a first heat source or sink (e.g., hot side heat source). The plurality of conductive shunts 606 can be coupled to a second heat source or sink (e.g., cold side heat sink), the plurality of conductive shunts 606 being disposed between the thermoelectric legs and the second heat source or sink such that the flexible substrate substantially does not impede thermal transport between the second heat source or sink and the plurality of conductive shunts.

Illustratively, FIG. 5C illustrates an exemplary method for forming a MLP for forming a thermoelectric module including a flexible lead frame, according to one exemplary embodiment of the present invention. This diagram is merely an example, which should not unduly limit the scope of the claims. One of ordinary skill in the art would recognize many variations, alternatives, and modifications. Method 70 illustrated in FIG. 5C includes providing a flexible substrate (71), providing a plurality of conductive shunts disposed over the flexible substrate (72), and providing a plurality of thermoelectric legs (73). Steps for providing such elements are described in greater detail elsewhere herein. Illustratively, the conductive shunts can be removably disposed on a first major surface of the flexible substrate. For example, conductive shunts 606 illustrated in FIG. 6 can be disposed on a first major surface of flexible substrate 605.

Method 70 illustrated in FIG. 5C further includes disposing the plurality of conductive shunts in thermal and electrical communication with the thermoelectric legs (74). For example, the first major surface of the flexible substrate can be arranged over the thermoelectric legs so as to bring the conductive shunts into alignment with suitable thermoelectric legs, and then can be lowered so as to bring the conductive shunts into direct thermal and electrical contact with the thermoelectric legs via a conductor. Exemplary methods for providing thermal and electrical communication between conductive shunts and thermoelectric legs are provided elsewhere herein. Illustratively, the conductive shunts can be coupled directly to the thermoelectric legs via a suitable conductor, e.g., solder, sintered silver, a diffusion bond, conductive epoxy, a transient liquid phase bond, braze, nanocopper, or diffusion solder. Such a step can result in an intermediate thermoelectric structure that includes a flexible substrate, a plurality of conductive shunts removably disposed over the flexible substrate, and a plurality of thermoelectric legs, the plurality of conductive shunts being in thermal and electrical communication with the thermoelectric legs. For example, conductive shunts 606 illustrated in FIG. 6 can suitably be placed in thermal and electrical communication with thermoelectric legs 602, 604.

Referring still to FIG. 5C, method 70 further includes, after disposing the plurality of conductive shunts in thermal and electrical communication with the thermoelectric legs, removing the flexible substrate (75). For example, the flexible substrate can be detached, e.g., mechanically peeled away from the conductive shunts, or can be dissolved or otherwise suitably removed. For example, flexible substrate 605 illustrated in FIG. 6 suitably can be detached from conductive shunts 606. Alternatively, the flexible substrate (e.g., flexible substrate 605) can be left in place, and optionally can be perforated so as to inhibit damage in a manner such as described further below with reference to FIGS. 9A-9C. Optionally, a suitable dielectric material can be disposed on the shunts after the flexible substrate is removed. This can include coating the shunts with a dielectric such as ceramic or bonding such ceramic to the shunts using the methods previously described. The resulting thermoelectric structure further can include a base plate coupled to at least a subset of the plurality of conductive legs 602, 604, and the method can include coupling such base plate to a first heat source or sink (e.g., hot side heat source). Method 70 further can include coupling the plurality of conductive shunts 606 to a second heat source or sink (e.g., cold side heat sink) such that the plurality of conductive shunts 606 are disposed between the thermoelectric legs and the second heat source or sink such that the flexible substrate substantially does not impede thermal transport between the second heat source or sink and the plurality of conductive shunts.

Accordingly, in certain embodiments such as described above with reference to FIGS. 5C and 6, the flexible substrate can be included as a carrier only and can be removed after the TE legs are coupled, e.g., soldered, silver sintered, diffusion bonded, bonded with conductive epoxy, brazed, transient liquid phase bonded, bonded with nanocopper, or bonded with diffusion solder, to the conductive shunts. Such an arrangement can allow the conductive shunts to “float” when in operation, rather than being bonded to a cold side substrate, and thus can be unconstrained so as to enhance movement as a result of thermal expansion. Such flexibility of movement can further help to relieve any stress buildup to thermal expansion mismatch between the hot and cold sides of the device package. For example, absent a substrate to which the conductive shunts are coupled, the primary potential source of thermal expansion mismatch can arise from the conductive shunts themselves being located on the cold side compared to the thermal expansion on the hot side. Confining the movement to the shunts themselves potentially can significantly reduce the characteristic length over which the thermal expansion takes place. Reducing or minimizing this characteristic length potentially can significantly reduce the relative movement between the hot and cold sides, thus reducing thermally-induced stress. Optionally, so as to provide additional dielectric strength for this embodiment, the shunts can be coated with a ceramic or other dielectric material. Another option can be to have dielectric pieces, e.g., pieces of a ceramic material such as alumina, silicon nitride, or aluminum nitride, bonded to the conductive shunts using an active metal braze or direct bonded copper process.

In another embodiment, the flexible substrate can be perforated in between one or more of the conductive shunts, such that the shunts are held together during assembly, but can separate under tension, thus reducing the characteristic thermal expansion length and reducing thermally induced stress. The perforations can be between every individual conductive shunt or can be between groups of shunts. For example, FIGS. 9A-9B are simplified diagrams showing alternative exemplary, flexible lead frames for a MLP for forming a thermoelectric module, according to one exemplary embodiment of the present invention. These diagrams are merely an example, which should not unduly limit the scope of the claims. One of ordinary skill in the art would recognize many variations, alternatives, and modifications. FIGS. 9A-9B illustrate thermoelectric structures that include a flexible substrate including a plurality of perforations defined therein, a plurality of conductive shunts disposed over the flexible substrate, and a plurality of thermoelectric legs. The plurality of conductive shunts are in thermal and electrical communication with the thermoelectric legs via thermal and electrical paths. Exemplary embodiments of the flexible substrate, conductive shunts, thermoelectric legs, and arrangements thereof, are provided elsewhere herein. The perforations defined through the flexible substrate are configured to rupture responsive to a temperature condition that otherwise would damage one or more of the thermal and electrical paths between the conductive shunts and the TE legs, and said rupture inhibits such damage. Additionally, FIGS. 9A-9B illustrate exemplary patterns of perforations in the flexible substrate, e.g., polyimide, that can add additional flexibility beyond that of the flexible substrate itself. Added flexibility can increases the compliant nature of the flexible substrate, and thereby can increase the ability of conductive shunts to behave as though mechanically detached from some or all other structures in the device. The resulting thermoelectric structure further can include a base plate coupled to at least a subset of the plurality of conductive legs and to a first heat source or sink (e.g., hot side heat source). The plurality of conductive shunts can be coupled to a second heat source or sink (e.g., cold side heat sink), the plurality of conductive shunts being disposed between the thermoelectric legs and the second heat source or sink such that the flexible substrate substantially does not impede thermal transport between the second heat source or sink and the plurality of conductive shunts.

Illustratively, the pattern of the perforations can be engineered so as to create one or more regions at which the polyimide layer can break apart or “unzip” if thermomechanical stress reaches a critical level. For example, if deformation caused by thermal expansion or another unfavorable stress reaches a critical value, then the perforations are designed to unzip in selected locations, thus absorbing the strain energy within the device that can otherwise cause failure at the rigid joints between one or more conductive shunts and one or more thermoelectric legs. Other patterns are illustrated elsewhere herein, or suitably may be envisioned based on the present teachings.

FIG. 9C illustrates an exemplary method of protecting a thermoelectric structure from an otherwise damaging thermal condition, according to one exemplary embodiment of the present invention. This diagram is merely an example, which should not unduly limit the scope of the claims. One of ordinary skill in the art would recognize many variations, alternatives, and modifications. Method 100 illustrated in FIG. 9C includes providing a thermoelectric structure including a flexible substrate, a plurality of conductive shunts disposed over the flexible substrate, and a plurality of thermoelectric legs in thermal and electrical communication with the conductive shunts via thermal and electrical paths (101).

Exemplary thermoelectric structures, and exemplary methods of making such structures, are provided elsewhere herein. Method 100 illustrated in FIG. 9C further includes defining perforations through the flexible substrate (102). Exemplary methods of defining perforations through a flexible substrate include cutting, e.g., mechanical cutting, cutting with a water jet, or laser cutting. Alternatively, the perforations can be defined during formation of the flexible substrate, thus obviating the need for a separate cutting step. Note that the perforations suitably can be defined at any point before, during, or after providing the thermoelectric structure in step 9C. For example, the perforations can be defined through the flexible substrate before bringing the plurality of thermoelectric legs into communication with the conductive shunts, e.g., before disposing the conductive shunts over the flexible substrate. In one nonlimiting embodiment in which the flexible substrate also includes apertures through which the legs and conductive shunts can thermally and electrically communicate with one another, with the flexible substrate being substantially out of the thermal and electrical paths, the perforations can be defined in a common step as are the apertures. The resulting thermoelectric structure further can include a base plate coupled to at least a subset of the plurality of conductive legs and to a first heat source or sink (e.g., hot side heat source). The plurality of conductive shunts can be coupled to a second heat source or sink (e.g., cold side heat sink), the plurality of conductive shunts being disposed between the thermoelectric legs and the second heat source or sink such that the flexible substrate substantially does not impede thermal transport between the second heat source or sink and the plurality of conductive shunts.

It should be appreciated that many advantages are provided by applying the present invention. The lead frame structure is very, or relatively, compliant and flexible which causes very, or relatively, low thermally-induced stresses due to CTE mismatches in a multi-leg package of a thermoelectric module under an ultra high, or high, temperature gradient. The proposed polyimide film based lead frame is very, or relatively, easy to handle during the MLP assembly. Polyimide is a poor thermal conductor (k=0.12 W/m K) so that in regions between thermoelectric legs, thermal losses due to thermal shorting from the hot side to cold side of the thermoelectric module can be reduced. In regions where the thermoelectric legs are to be bonded with conductive shunts, holes or apertures can be provided, e.g., cut, in the flexible lead frame, e.g., polyimide film, so as to allow thermal heat flow between the thermoelectric legs to the conductive shunts substantially without the flexible lead frame adding any significant thermal resistance.

In some embodiments, a thermoelectric structure includes a flexible substrate including a plurality of apertures defined therethrough; a plurality of conductive shunts disposed over the flexible substrate; and a plurality of thermoelectric legs. The conductive shunts can be in thermal and electrical communication with the thermoelectric legs via thermal and electrical paths passing through the apertures. The flexible substrate can be substantially out of the thermal and electrical paths. Embodiments of such a thermoelectric structure are described, for example, with reference to FIGS. 1, 2, 3, 4A-4D, 5A, 5B, 7A, 7B, 8A-8C, 9A, 9B, and 9C.

In some embodiments, a method of making a thermoelectric structure includes providing a flexible substrate including a plurality of apertures defined therethrough; providing a plurality of conductive shunts disposed over the flexible substrate; and providing a plurality of thermoelectric legs. The conductive shunts can be in thermal and electrical communication with the thermoelectric legs via thermal and electrical paths passing through the apertures. The flexible substrate can be substantially out of the thermal and electrical paths. Embodiments of such a method are described, for example, with reference to FIGS. 5A, 5B, and 9C.

In some embodiments, a thermoelectric structure includes a flexible substrate; a plurality of conductive shunts disposed over the flexible substrate; a plurality of thermoelectric legs; and a circuit board coupled to the flexible substrate. The conductive shunts can be in thermal and electrical communication with the thermoelectric legs. A bend in the flexible substrate can be disposed between the plurality of conductive shunts and the circuit board. Embodiments of such a thermoelectric structure are described, for example, with reference to FIGS. 1, 2, 3, 4A-4D, 5A, 5B, 6, 7A, 7B, 8A-8C, 9A, 9B, and 9C.

In some embodiments, a method of making a thermoelectric structure includes providing a flexible substrate; providing a plurality of conductive shunts disposed over the flexible substrate; providing a plurality of thermoelectric legs; providing a circuit board; bending the flexible substrate so as to define a bend in the flexible substrate; and coupling the circuit board to the flexible substrate. The conductive shunts can be in thermal and electrical communication with the thermoelectric legs. The bend in the flexible substrate can be disposed between the plurality of conductive shunts and the circuit board. Embodiments of such a method are described, for example, with reference to FIGS. 5A, 5B, and 9C.

In some embodiments, a thermoelectric structure includes a plurality of conductive shunts; and a plurality of thermoelectric legs. The plurality of conductive shunts are in direct thermal and electrical communication with the thermoelectric legs via a conductor. Embodiments of such a structure are described, for example, with reference to FIGS. 5C and 6.

In some embodiments, an intermediate thermoelectric structure includes a flexible substrate; a plurality of conductive shunts removably disposed over the flexible substrate; and a plurality of thermoelectric legs. The plurality of conductive shunts can be in thermal and electrical communication with the thermoelectric legs. Embodiments of such a structure are described, for example, with reference to FIGS. 5C and 6.

In some embodiments, a method of making a thermoelectric structure includes providing a flexible substrate; providing a plurality of conductive shunts disposed over the flexible substrate; providing a plurality of thermoelectric legs; disposing the plurality of conductive shunts in thermal and electrical communication with the thermoelectric legs; and after disposing the plurality of conductive shunts in thermal and electrical communication with the thermoelectric legs, removing the flexible substrate. Embodiments of such a method are described, for example, with reference to FIG. 5C.

In some embodiments, a thermoelectric structure includes a flexible substrate including a plurality of perforations defined therein; a plurality of conductive shunts disposed over the flexible substrate; and a plurality of thermoelectric legs. The plurality of conductive shunts can be in thermal and electrical communication with the thermoelectric legs via thermal and electrical paths. The perforations can be configured to rupture responsive to a temperature condition that otherwise would damage one or more of the thermal and electrical paths, said rupture inhibiting such damage. Embodiments of such a thermoelectric structure are described, for example, with reference to FIGS. 1, 2, 3, 4A-4D, 5A, 5B, 6, 7A, 7B, 8A-8C, 9A, 9B, and 9C.

In some embodiments, a method of protecting a thermoelectric structure is provided. The thermoelectric structure includes a flexible substrate, a plurality of conductive shunts disposed over the flexible substrate, and a plurality of thermoelectric legs in thermal and electrical communication with the conductive shunts via thermal and electrical paths. The method can include defining perforations through the flexible substrate; and rupturing the flexible substrate along one or more of the perforations responsive to a thermal condition that otherwise would damage one or more of the thermal and electrical paths, said rupture inhibiting such damage. Embodiments of such a method are described, for example, with reference to FIG. 9C.

It is also understood that the examples and embodiments described herein are for illustrative purposes only and that various modifications or changes in light thereof will be suggested to persons skilled in the art and are to be included within the spirit and purview of this application and scope of the claims.

What is claimed is:

1. A thermoelectric structure, comprising:
a flexible substrate including a plurality of apertures defined therethrough;
a plurality of conductive shunts disposed over the flexible substrate; and
a plurality of thermoelectric legs,
the conductive shunts being in thermal and electrical communication with the thermoelectric legs via thermal and electrical paths passing through the apertures, the flexible substrate being substantially out of the thermal and electrical paths.

2. The thermoelectric structure of claim 1, the thermoelectric structure further being configured to be coupled to a first heat source or sink and to a second heat source or sink, the thermoelectric structure further comprising:
a base plate coupled to at least a subset of the plurality of conductive legs and to the first heat source or sink,
the plurality of conductive shunts being coupled to the second heat source or sink, the plurality of conductive shunts being disposed between the flexible substrate and the second heat source or sink such that the flexible substrate substantially does not impede thermal transport between the second heat source or sink and the plurality of conductive shunts.

3. The thermoelectric structure of claim 1, wherein the flexible substrate includes polyimide.

4. The thermoelectric structure of claim 1, wherein the plurality of thermoelectric legs includes an N-type thermoelectric leg and a P-type thermoelectric leg, a conductive shunt being in thermal and electrical communication with the N-type thermoelectric leg and with the P-type thermoelectric leg.

5. The thermoelectric structure of claim 4, wherein the conductive shunt is in thermal and electrical communication with the N-type thermoelectric leg via a first aperture, and wherein the conductive shunt is in thermal and electrical communication with the P-type thermoelectric leg via a second aperture that is different than the first aperture.

6. The thermoelectric structure of claim 1, wherein the plurality of thermoelectric legs includes an N-type thermoelectric leg and two or more P-type thermoelectric legs, a conductive shunt being in thermal and electrical communication with the N-type thermoelectric leg and with the two or more P-type thermoelectric legs.

7. The thermoelectric structure of claim 6, wherein the conductive shunt is in thermal and electrical communication with the N-type thermoelectric leg via a first aperture, and wherein the conductive shunt is in thermal and electrical communication with each of the two or more P-type thermoelectric legs via corresponding apertures that are different than the first aperture.

8. The thermoelectric structure of claim 1, further comprising a circuit board coupled to the flexible substrate, a bend in the flexible substrate being disposed between the plurality of conductive shunts and the circuit board.

9. The thermoelectric structure of claim 1, the flexible substrate further including a plurality of perforations defined therethrough, the perforations being configured to rupture responsive to a temperature condition that otherwise would damage one or more of the thermal and electrical paths, said rupture inhibiting such damage.

10. The thermoelectric structure of claim 1, further comprising a base plate to which the plurality of thermoelectric legs are coupled, a notch being defined in the base plate so as to partially relieve thermal stress and allow a small degree of bending flexibility.

11. The thermoelectric structure of claim 1, wherein the plurality of thermoelectric legs includes two or more N-type thermoelectric legs and a P-type thermoelectric leg, a conductive shunt being in thermal and electrical communication with the two or more N-type thermoelectric legs and with the P-type thermoelectric leg.

12. The thermoelectric structure of claim 11, wherein the conductive shunt is in thermal and electrical communication with each of the two or more N-type thermoelectric legs via one or more first apertures, and wherein the conductive shunt is in thermal and electrical communication with the P-type thermoelectric leg via a corresponding aperture that is different than the first apertures.

13. The thermoelectric structure of claim 1, wherein the plurality of thermoelectric legs includes a plurality of N-type thermoelectric legs having a first area and a plurality of P-type thermoelectric legs having a second area, a pattern of the apertures being selected so as to maximize a packing fraction of the thermoelectric legs and so as to optimize a ratio of the first area to the second area.

14. The thermoelectric structure of claim 13, wherein each N-type thermoelectric leg has a first aspect ratio and wherein each the P-type thermoelectric leg has a second aspect ratio, the pattern of the apertures further being selected so as to optimize a ratio of the first aspect ratio to the second aspect ratio.

15. A method of making a thermoelectric structure, the method comprising:
providing a flexible substrate including a plurality of apertures defined therethrough;
providing a plurality of conductive shunts disposed over the flexible substrate; and
providing a plurality of thermoelectric legs,
the conductive shunts being in thermal and electrical communication with the thermoelectric legs via thermal and electrical paths passing through the apertures, the flexible substrate being substantially out of the thermal and electrical paths.

16. The method of claim 15, further comprising:
providing a base plate;
coupling the base plate to at least a subset of the plurality of conductive legs and to the first heat source or sink; and
coupling the plurality of conductive shunts o the second heat source or sink such that the plurality of conductive shunts is disposed between the flexible substrate and the second heat source or sink such that the flexible substrate substantially does not impede thermal transport between the second heat source or sink and the plurality of conductive shunts.

17. The method of claim 15, wherein the flexible substrate includes polyimide.

18. The method of claim 15, further comprising defining the apertures through the flexible substrate using cutting.

19. The method of claim 18, wherein the cutting comprises laser cutting.

20. The method of claim 15, wherein the plurality of thermoelectric legs includes an N-type thermoelectric leg and a P-type thermoelectric leg, the method comprising placing a conductive shunt in thermal and electrical communication with the N-type thermoelectric leg and with the P-type thermoelectric leg.

21. The method of claim 20, comprising placing the conductive shunt in thermal and electrical communication with the N-type thermoelectric leg via a first aperture, and placing the conductive shunt in thermal and electrical communication with the P-type thermoelectric leg via a second aperture that is different than the first aperture.

22. The method of claim 15, wherein the plurality of thermoelectric legs includes an N-type thermoelectric leg and two or more P-type thermoelectric legs, the method comprising placing a conductive shunt in thermal and electrical communication with the N-type thermoelectric leg and with the two or more P-type thermoelectric legs.

23. The method of claim 22, comprising placing the conductive shunt in thermal and electrical communication with the N-type thermoelectric leg via a first aperture, and placing the conductive shunt in thermal and electrical communication with each of the two or more P-type thermoelectric legs via corresponding apertures that are different than the first aperture.

24. The method of claim 15, further comprising coupling a circuit board to the flexible substrate and defining a bend in the flexible substrate, the bend being disposed between the plurality of conductive shunts and the circuit board.

25. The method of claim 15, further comprising defining through the flexible substrate a plurality of perforations, the perforations being configured to rupture responsive to a temperature condition that otherwise would damage one or more of the thermal and electrical paths, said rupture inhibiting such damage.

26. The method of claim 15, further comprising coupling the plurality of thermoelectric legs to a base plate and defining a notch in the base plate so as to partially relieve thermal stress and allow a small degree of bending flexibility

27. The method of claim 15, wherein the plurality of thermoelectric legs includes two or more N-type thermoelectric legs and a P-type thermoelectric leg, the method including placing a conductive shunt in thermal and electrical communication with the two or more N-type thermoelectric legs and with the P-type thermoelectric leg.

28. The method of claim 27, further comprising placing the conductive shunt in thermal and electrical communication with each of the two or more N-type thermoelectric legs via one or more first apertures, and placing the conductive shunt in thermal and electrical communication with the P-type thermoelectric leg via a corresponding aperture that is different than the first apertures.

29. The method of claim 15, wherein the plurality of thermoelectric legs includes a plurality of N-type thermoelectric legs having a first area and a plurality of P-type thermoelectric legs having a second area, the method further comprising selecting a pattern of the apertures so as to maximize a packing fraction of the thermoelectric legs and so as to optimize a ratio of the first area to the second area.

30. The method of claim 29, wherein each N-type thermoelectric leg has a first aspect ratio and wherein each the P-type thermoelectric leg has a second aspect ratio, the method further comprising selecting the pattern of the apertures so as to optimize a ratio of the first aspect ratio to the second aspect ratio.

31. A thermoelectric structure, comprising:
a flexible substrate;
a plurality of conductive shunts disposed over the flexible substrate;
a plurality of thermoelectric legs; and
a circuit board coupled to the flexible substrate,
the conductive shunts being in thermal and electrical communication with the thermoelectric legs,
a bend in the flexible substrate being disposed between the plurality of conductive shunts and the circuit board.

32. A method of making a thermoelectric structure, the method comprising:
providing a flexible substrate;
providing a plurality of conductive shunts disposed over the flexible substrate;
providing a plurality of thermoelectric legs;
providing a circuit board;
bending the flexible substrate so as to define a bend in the flexible substrate; and
coupling the circuit board to the flexible substrate,
the conductive shunts being in thermal and electrical communication with the thermoelectric legs,
the bend in the flexible substrate being disposed between the plurality of conductive shunts and the circuit board.

33. A thermoelectric structure, comprising:
a plurality of conductive shunts; and
a plurality of thermoelectric legs,
the plurality of conductive shunts being in direct thermal and electrical communication with the thermoelectric legs via a conductor.

34. The thermoelectric structure of claim 33, further comprising a dielectric material disposed over the conductive shunts.

35. An intermediate thermoelectric structure, comprising:
a flexible substrate;
a plurality of conductive shunts removably disposed over the flexible substrate; and
a plurality of thermoelectric legs,
the plurality of conductive shunts being in thermal and electrical communication with the thermoelectric legs.

36. A method of making a thermoelectric structure, the method comprising:
providing a flexible substrate;
providing a plurality of conductive shunts disposed over the flexible substrate;
providing a plurality of thermoelectric legs;
disposing the plurality of conductive shunts in thermal and electrical communication with the thermoelectric legs; and
after disposing the plurality of conductive shunts in thermal and electrical communication with the thermoelectric legs, removing the flexible substrate.

37. A thermoelectric structure, comprising:
a flexible substrate including a plurality of perforations defined therein;
a plurality of conductive shunts disposed over the flexible substrate; and
a plurality of thermoelectric legs,
the plurality of conductive shunts being in thermal and electrical communication with the thermoelectric legs via thermal and electrical paths,
the perforations being configured to rupture responsive to a temperature condition that otherwise would damage one or more of the thermal and electrical paths, said rupture inhibiting such damage.

38. A method of protecting a thermoelectric structure, the thermoelectric structure including a flexible substrate, a plurality of conductive shunts disposed over the flexible substrate, and a plurality of thermoelectric legs in thermal and electrical communication with the conductive shunts via thermal and electrical paths, the method including:
defining perforations through the flexible substrate; and
rupturing the flexible substrate along one or more of the perforations responsive to a thermal condition that otherwise would damage one or more of the thermal and electrical paths, said rupture inhibiting such damage.
